(19) United States
(12) Patent Application Publication
(10) Pub. No.: US 2019/0089323 A1
(43) Pub. Date: Mar. 21, 2019

(54) IMPEDANCE MATCHING CIRCUIT, RADIO-FREQUENCY FRONT-END CIRCUIT, AND COMMUNICATION DEVICE

(71) Applicant: Murata Manufacturing Co., Ltd., Kyoto (JP)

(72) Inventor: Koji NOSAKA, Kyoto (JP)

(21) Appl. No.: 16/192,195

(22) Filed: Nov. 15, 2018

Related U.S. Application Data
(63) Continuation of application No. PCT/JP2017/016107, filed on Apr. 21, 2017.

(30) Foreign Application Priority Data
May 20, 2016 (JP) 2016-101962

(51) Int. Cl. H03H 7/38; H01Q 1/50; H03H 9/72; H03H 9/64

(52) U.S. Cl. CPC H03H 7/38; H03H 9/6483; H03H 9/725; H01Q 1/50

(57) ABSTRACT

An impedance matching circuit (31) includes inductors (311L and 312L) that are connected in series, a switch (311S) that includes a first terminal connected to an end of the inductor (311L) and a second terminal and that switches between connection and disconnection between the first terminal and the second terminal, a switch (312S) that includes a third terminal connected to a connection point of the other end of the inductor (311L) and an end of the inductor (312L) and a fourth terminal and that switches between connection and disconnection between the third terminal and the fourth terminal, a switch (313S) that includes a fifth terminal connected to the other end of the inductor (312L) and a sixth terminal and that switches between connection and disconnection between the fifth terminal and the sixth terminal. The second terminal, the fourth terminal, and the sixth terminal are connected to each other.

This is a continuation of International Application No. PCT/JP2017/016107 filed on Apr. 21, 2017 which claims priority from Japanese Patent Application No. 2016-101962 filed on May 20, 2016. The contents of these applications are incorporated herein by reference in their entireties.

### BACKGROUND OF THE DISCLOSURE

### Field of the Disclosure

The present disclosure relates to an impedance matching circuit, a radio-frequency front-end circuit, and a communication device.

### Description of the Related Art

A radio-frequency front-end circuit that selectively allows radio-frequency signals in frequency bands to pass therethrough has been put to practical use to support the combination of, for example, a multi-mode and a multi-band of a mobile communication device.

Patent Document 1 discloses a SAW demultiplexer that includes two ladder SAW filters having different pass bands that are connected to a common terminal. The SAW demultiplexer includes an impedance matching circuit that includes an inductor and a capacitor and that is disposed between an antenna and the common terminal.

Patent Document 1: Japanese Unexamined Patent Application Publication No. 2003-332885

### BRIEF SUMMARY OF THE DISCLOSURE

In the case where a radio-frequency front-end circuit is used in a small number of bands, an impedance matching circuit having a fixed impedance is disposed between an antenna element and a common terminal as described above, and this achieves impedance matching between the antenna element and radio-frequency circuits on signal paths as in the SAW demultiplexer disclosed in Patent Document 1.

However, the use of a larger number of bands makes it difficult for the impedance matching circuit alone to achieve impedance matching suitable for filter elements. In view of this, it can be thought that the state of the impedance of the impedance matching circuit is changed in accordance with the combinations of the antenna element and the filter elements that are selectively connected to each other. In this case, the required number of the inductance values of the impedance matching circuit is equal to the number of the combinations. For this reason, inductors corresponding to the required inductance values are needed. However, the larger the inductance values, the larger the size of the inductors. Accordingly, there is a problem in that the size of the impedance matching circuit increases as the number of the inductance values increases (the number of the bands increases).

The present disclosure has been accomplished to solve the above problem, and it is an object of the present disclosure to provide an impedance matching circuit, a radio-frequency front-end circuit and a communication device that ensure the range of the variable inductance values with a decreased size.

To achieve the above object, an impedance matching circuit according to an aspect of the present disclosure is disposed between a plurality of radio-frequency circuits and that matches impedances when two or more radio-frequency circuits selected from the plurality of radio-frequency circuits are connected. The impedance matching circuit includes a first inductor and a second inductor that are connected in series, a first switch that includes a first terminal and a second terminal and that switches between connection and disconnection between the first terminal and the second terminal, the first terminal being connected to an end of the first inductor, a second switch that includes a third terminal and a fourth terminal and that switches between connection and disconnection between the third terminal and the fourth terminal, the third terminal being connected to a connection point of the other end of the first inductor and an end of the second inductor, and a third switch that includes a fifth terminal and a sixth terminal and that switches between connection and disconnection between the fifth terminal and the sixth terminal, the fifth terminal being connected to the other end of the second inductor. The second terminal, the fourth terminal, and the sixth terminal are connected to each other.

In the case where the state of the impedance of the impedance matching circuit is changed in accordance with the combinations of the selectively connected radio-frequency circuits, the required number of the inductance values of the impedance matching circuit is equal to the number of the combinations. For this reason, inductors corresponding to the required inductance values are needed. However, the larger the inductance values, the larger the size of the inductors, and the larger the number of the inductance values, the larger the size of the impedance matching circuit. From this perspective, the larger the number of the bands, the larger the size of the circuit, for example, in the case where a multi-band front-end circuit of a cellular phone is equipped with an impedance matching circuit.

With the above configuration, however, four inductance values of 0, L1, L2, and (L1+L2) can be selected with the two inductors when the switches that are connected to the terminals of the two inductors that are connected in series are switched on (connection) or off (disconnection), for example, to set the inductance value of the first inductor to L1 and set the inductance value of the second inductor to L2. That is, there is no need for a large inductor having an inductance value of (L1+L2), and the two inductors having inductance values smaller than (L1+L2) enable the inductance values to be selected stepwise from 0 to (L1+L2). In the case where three inductors (there is no need for the inductors when each inductance value is 0) correspond to four inductance values of 0, L1, L2, and (L1+L2), the required number of the inductance values is 2×(L1+L2) in total. Accordingly, the above configuration according to the present disclosure ensures the range of the variable inductance values and enables the size of the circuit to be decreased.

The impedance matching circuit may further include a first input-output terminal and a second input-output terminal that are connected to the two or more radio-frequency circuits. The first inductor and the second inductor may be connected in series on a path connecting the first input-output terminal and the second input-output terminal to each other.

This ensures the range of a variable reactance component in the impedance of the impedance matching circuit and enables the size of the circuit to be decreased.

The impedance matching circuit may further include a first input-output terminal and a second input-output terminal that are connected to the plurality of radio-frequency circuits. The first inductor and the second inductor may be connected in series between a path connecting the first input-output terminal and the second input-output terminal to each other and a ground terminal.

This ensures the range of a variable susceptance component in the admittance of the impedance matching circuit and enables the size of the circuit can be decreased.

The impedance matching circuit may further include a capacitor that is connected to the first inductor or the second inductor, and a fourth switch that is connected to the capacitor.

This enables the range of the variable impedance or admittance of the impedance matching circuit to be widened.

The impedance matching circuit may further include a first input-output terminal and a second input-output terminal that are connected to the two or more radio-frequency circuits, a third inductor and a fourth inductor that are connected in series, a fifth switch that includes a seventh terminal and an eighth terminal and that switches between connection and disconnection between the seventh terminal and the eighth terminal, the seventh terminal being connected to an end of the third inductor, a sixth switch that includes a ninth terminal and a tenth terminal and that switches between connection and disconnection between the ninth terminal and the tenth terminal, the ninth terminal being connected to a connection point of the other end of the third inductor and an end of the fourth inductor, and a seventh switch that includes an eleventh terminal and a twelfth terminal and that switches between connection and disconnection between the eleventh terminal and the twelfth terminal, the eleventh terminal being connected to the other end of the fourth inductor. The eighth terminal, the tenth terminal, and the twelfth terminal are connected to each other. The first inductor and the second inductor are connected in series on a path connecting the first input-output terminal and the second input-output terminal to each other. The third inductor and the fourth inductor are connected in series between the path connecting the first input-output terminal and the second input-output terminal to each other and a ground terminal.

This enables the reactance component in the impedance of the impedance matching circuit to be variable and enables the susceptance component in the admittance of the impedance matching circuit to be variable. Accordingly, the degree of freedom of impedance matching is greatly increased, and the size of the circuit can be decreased.

The impedance matching circuit may further include a first input-output terminal and a second input-output terminal that are connected to the two or more radio-frequency circuits, a third inductor and a fourth inductor that are connected in series, a fifth switch that includes a seventh terminal and an eighth terminal and that switches between connection and disconnection between the seventh terminal and the eighth terminal, the seventh terminal being connected to an end of the third inductor, a sixth switch that includes a ninth terminal and a tenth terminal and that switches between connection and disconnection between the ninth terminal and the tenth terminal, the ninth terminal being connected to a connection point of the other end of the third inductor and an end of the fourth inductor, and a seventh switch that includes an eleventh terminal and a twelfth terminal and that switches between connection and disconnection between the eleventh terminal and the twelfth terminal, the eleventh terminal being connected to the other end of the fourth inductor. The eighth terminal, the tenth terminal, and the twelfth terminal are connected to each other. The first inductor and the second inductor are connected in series on a path connecting the first input-output terminal and the second input-output terminal to each other. The third inductor and the fourth inductor are connected in series between the second terminal and a ground terminal.

This enables the reactance component in the impedance of the impedance matching circuit to be variable and enables the susceptance component in the admittance of the impedance matching circuit to be variable. Accordingly, the degree of freedom of impedance matching is greatly increased, and the size of the circuit can be decreased.

The first inductor and the second inductor may be formed of a coil pattern that is contained in a circuit board.

This enables the inductors having a total inductance value smaller than that according to the existing technique to ensure the desired range of the variable inductance and enables the area of the coil pattern or the number of stacked layers thereof to be decreased. Consequently, the size of the circuit board can be decreased.

The first switch, the second switch, and the third switch may be mounted on a main surface of the circuit board.

This enables the area of the impedance matching circuit to be decreased because the first switch, the second switch, and the third switch are stacked on the first inductor and the second inductor.

The first switch, the second switch, and the third switch may be diode switches or FET switches composed of GaAs or a CMOS.

This enables the size and cost of the impedance matching circuit to be decreased.

A radio-frequency front-end circuit according to an aspect of the present disclosure includes the above impedance matching circuit that is connected to an antenna element or a demultiplexer, a plurality of filters that have different pass bands, and a switch circuit that switches between connections between at least one of the plurality of filters and the impedance matching circuit.

This enables the radio-frequency front-end circuit to be small and enables the impedances of the filters and the antenna element or the demultiplexer to be successfully matched even when the states of connections between the filters and the antenna element or the demultiplexer are changed.

A radio-frequency front-end circuit according to an aspect of the present disclosure includes an amplifier circuit that amplifies a radio-frequency signal, the above impedance matching circuit that is connected to the amplifier circuit, a plurality of filters that have different pass bands, and a switch circuit that switches between connections between at least one of the plurality of filters and the impedance matching circuit.

This enables the radio-frequency front-end circuit to be small and enables the impedances of the filters and the amplifier circuit to be successfully matched even when the states of connections between the filters and the amplifier circuit are changed.

A communication device according to an aspect of the present disclosure includes the above radio-frequency front-end circuit, a control unit that controls states of connections between the first switch, the second switch, and the third switch, and a RF-signal processing circuit that processes a radio-frequency signal. The control unit selects a mode, on a basis of a frequency band that is selected, from (1) a first mode in which the first switch, the second switch, and the third switch are left in a connection state to minimize an inductance component, (2) a second mode in which the first switch and the second switch are left in the connection state and the third switch is left in a disconnection state, (3) a third mode in which the second switch and the third switch are left in the connection state and the first switch is left in the disconnection state, and (4) a fourth mode in which the first switch, the second switch, and the third switch are left in the disconnection state to maximize the inductance component.

This enables the communication device to be small and enables impedances to be successfully matched in accordance with the selected frequency band.

According to the present disclosure, the range of the variable inductance values is ensured, and the size of the impedance matching circuit, the radio-frequency front-end circuit, and the communication device can be decreased.

### BRIEF DESCRIPTION OF THE SEVERAL VIEWS OF THE DRAWINGS

FIG. 1 is a circuit diagram of a radio-frequency front-end circuit and a peripheral circuit thereof according to an embodiment.

FIG. 2A is a circuit diagram of an impedance matching circuit according to the embodiment.

FIG. 2B is a circuit diagram of an impedance matching circuit according to a first modification to the embodiment.

FIG. 3A illustrates a Smith chart indicating variation in the impedance of the impedance matching circuit according to the embodiment.

FIG. 3B illustrates a Smith chart indicating variation in the impedance of the impedance matching circuit according to the first modification to the embodiment.

FIG. 4A illustrates a first example of the configuration of the impedance matching circuit according to the embodiment.

FIG. 4B illustrates a second example of the configuration of the impedance matching circuit according to the embodiment.

FIG. 5A is a circuit diagram of an impedance matching circuit according to a second modification to the embodiment.

FIG. 5B is a circuit diagram of an impedance matching circuit according to a third modification to the embodiment.

FIG. 6A illustrates a Smith chart indicating variation in the impedance of the impedance matching circuit according to the second modification to the embodiment.

FIG. 6B illustrates a Smith chart indicating variation in the impedance of the impedance matching circuit according to the third modification to the embodiment.

FIG. 7A is a circuit diagram of an impedance matching circuit according to a fourth modification to the embodiment.

FIG. 7B is a circuit diagram of an impedance matching circuit according to a fifth modification to the embodiment.

FIG. 8A illustrates a Smith chart indicating variation in the impedance of the impedance matching circuit according to the fourth modification to the embodiment.

FIG. 8B illustrates a Smith chart indicating variation in the impedance of the impedance matching circuit according to the fourth modification to the embodiment.

FIG. 8C illustrates a Smith chart indicating variation in the impedance of the impedance matching circuit according to the fourth modification to the embodiment.

FIG. 8D illustrates a Smith chart indicating variation in the impedance of the impedance matching circuit according to the fourth modification to the embodiment.

FIG. 9A illustrates a Smith chart indicating variation in the impedance of the impedance matching circuit according to the fifth modification to the embodiment.

FIG. 9B illustrates a Smith chart indicating variation in the impedance of the impedance matching circuit according to the fifth modification to the embodiment.

FIG. 9C illustrates a Smith chart indicating variation in the impedance of the impedance matching circuit according to the fifth modification to the embodiment.

FIG. 9D illustrates a Smith chart indicating variation in the impedance of the impedance matching circuit according to the fifth modification to the embodiment.

FIG. 10A is a circuit diagram of an impedance matching circuit according to a sixth modification to the embodiment.

FIG. 10B is a circuit diagram of an impedance matching circuit according to a seventh modification to the embodiment.

FIG. 10C is a circuit diagram of an impedance matching circuit according to an eighth modification to the embodiment.

FIG. 11 illustrates a Smith chart indicating variation in the impedances of the impedance matching circuits according to the sixth to eighth modifications to the embodiment.

FIG. 12A illustrates a Smith chart indicating a state of impedance matching in Band8 and Band20 in a comparative example.

FIG. 12B illustrates a Smith chart indicating a state of impedance matching in Band8 and Band20 according to an example.

FIG. 13A illustrates a part of a radio-frequency front-end circuit according to a ninth modification to the embodiment.

FIG. 13B illustrates a part of a radio-frequency front-end circuit according to a tenth modification to the embodiment.

### DETAILED DESCRIPTION OF THE DISCLOSURE

An embodiment of the present disclosure will hereinafter be described in detail with reference to examples and the drawings. The embodiment described below is a comprehensive or specific example. In the following description according to the embodiment, numerical values, shapes, materials, components, and the arrangement and connection form of the components are described by way of example and do not limit the present disclosure. Among the components according to the embodiment below, components that are not recited in the independent claim are described as optional components. The size of each component illustrated in the drawings or the ratio of the size is not necessarily illustrated strictly.

### Embodiment

### 1.1 CIRCUIT CONFIGURATION OF RADIO-FREQUENCY FRONT-END CIRCUIT

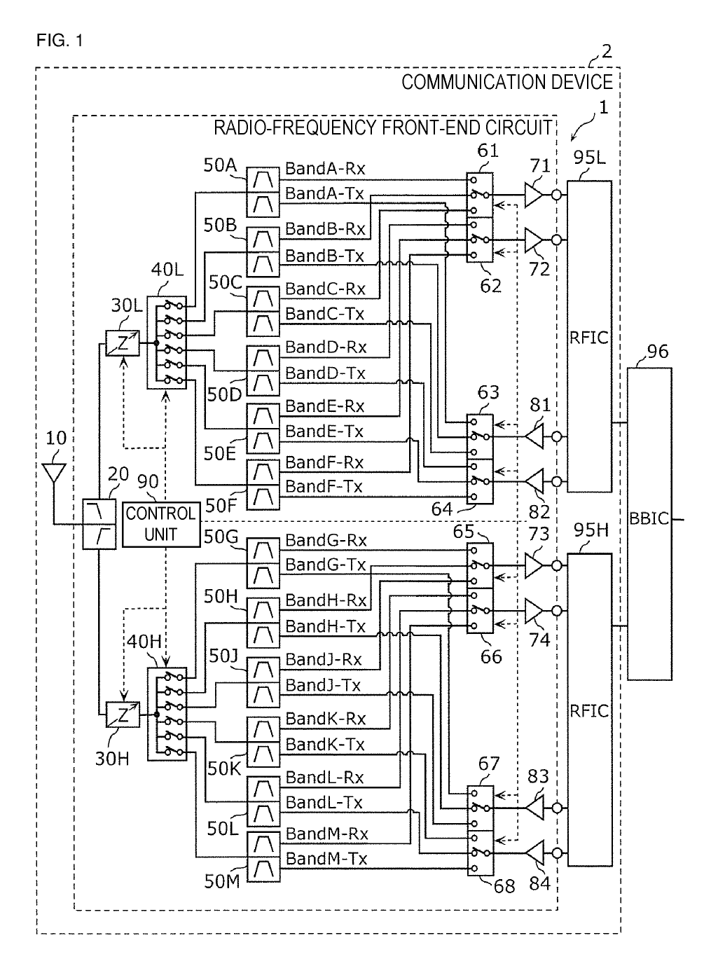

FIG. 1 is a circuit diagram of a radio-frequency front-end circuit and a peripheral circuit thereof according to an embodiment. FIG. 1 illustrates a radio-frequency front-end circuit 1 according to the embodiment, an antenna element 10, RF-signal processing circuits 95L and 95H, and a baseband signal processing circuit 96. The radio-frequency front-end circuit 1 and the antenna element 10 are disposed, for example, at a front end of a cellular phone that supports a multi-mode and a multi-band. The radio-frequency front-end circuit 1 and the RF-signal processing circuits 95L and 95H form a communication device 2.

The radio-frequency front-end circuit 1 includes a diplexer 20, impedance matching circuits 30L and 30H, switch circuits 40L and 40H, duplexers 50A, 50B, 50C, 50D, 50E, 50F, 50G, 50H, 50J, 50K, 50L, and 50M, switch circuits 61, 62, 63, 64, 65, 66, 67, and 68, reception amplifier circuits 71, 72, 73, and 74, transmission amplifier circuits 81, 82, 83, and 84, and a control unit 90.

The radio-frequency front-end circuit 1 is a multi-carrier transceiver that supports the multi-mode and the multi-band and that has signal paths through which wireless signals in frequency bands are transmitted and received. According to the embodiment, the frequency bands include BandA to BandF belonging to a low band group and BandG to BandM belonging to a high band group. Radio-frequency signals in the bands are processed in, for example, a frequency division duplex (FDD) method, and accordingly, the duplexers 50A to 50M for simultaneous transmission and reception are disposed on the respective signal paths of the bands.

The diplexer 20 divides wireless signals that are inputted from the antenna element 10 into the low band group (for example, 700 MHz to 1 GHz) and the high band group (for example, 1.7 GHz to 2.2 GHz) and outputs the signals to the impedance matching circuits 30L and 30H. The diplexer 20 outputs transmission signals that are inputted from the signal paths to the antenna element 10.

The impedance matching circuit 30L changes the impedance in accordance with the bands that are used for impedance matching between the signal paths belonging to the low band group and the antenna element 10 (diplexer 20).

The impedance matching circuit 30H changes the impedance in accordance with the bands that are used for impedance matching between the signal paths belonging to the high band group and the antenna element 10 (diplexer 20).

The impedance matching circuits 30L and 30H, which are main features of the present disclosure, will be described below in detail in a section of the configuration and operation of the impedance matching circuits.

The switch circuit 40L switches between connections between the antenna element 10 and the signal paths in a manner in which the antenna element 10 is connected to at least one of the signal paths belonging to the low band group. The switch circuit 40H switches between connections between the antenna element 10 and the signal paths in a manner in which the antenna element 10 is connected to at least one of the signal paths belonging to the high band group.

The duplexer 50A is a demultiplexer that includes a transmission filter that selectively allows a transmission band of BandA in the low band group to pass and a reception filter that selectively allows a reception band of BandA to pass. The duplexer 50B is a demultiplexer that includes a transmission filter that selectively allows a transmission band of BandB in the low band group to pass and a reception filter that selectively allows a reception band of BandB to pass. The duplexer 50C is a demultiplexer that includes a transmission filter that selectively allows a transmission band of BandC in the low band group to pass and a reception filter that selectively allows a reception band of BandC to pass. The duplexer 50D is a demultiplexer that includes a transmission filter that selectively allows a transmission band of BandD in the low band group to pass and a reception filter that selectively allows a reception band of BandD to pass. The duplexer 50E is a demultiplexer that includes a transmission filter that selectively allows a transmission band of BandE in the low band group to pass and a reception filter that selectively allows a reception band of BandE to pass. The duplexer 50F is a demultiplexer that includes a transmission filter that selectively allows a transmission band of BandF in the low band group to pass and a reception filter that selectively allows a reception band of BandF to pass.

The duplexer 50G is a demultiplexer that includes a transmission filter that selectively allows a transmission band of BandG in the high band group to pass and a reception filter that selectively allows a reception band of BandG to pass. The duplexer 50H is a demultiplexer that includes a transmission filter that selectively allows a transmission band of BandH in the high band group to pass and a reception filter that selectively allows a reception band of BandH to pass. The duplexer 50J is a demultiplexer that includes a transmission filter that selectively allows a transmission band of BandJ in the high band group to pass and a reception filter that selectively allows a reception band of BandJ to pass. The duplexer 50K is a demultiplexer that includes a transmission filter that selectively allows a transmission band of BandK in the high band group to pass and a reception filter that selectively allows a reception band of BandK to pass. The duplexer 50L is a demultiplexer that includes a transmission filter that selectively allows a transmission band of BandL in the high band group to pass and a reception filter that selectively allows a reception band of BandL to pass. The duplexer 50M is a demultiplexer that includes a transmission filter that selectively allows a transmission band of BandM in the high band group to pass and a reception filter that selectively allows a reception band of BandM to pass.

The switch circuit 61 switches between connections between the reception amplifier circuit 71 and reception signal paths in a manner in which the reception amplifier circuit 71 is connected to at least one of the reception signal paths of BandA, BandB, and BandC belonging to the low band group. The switch circuit 62 switches between connections between the reception amplifier circuit 72 and reception signal paths in a manner in which the reception amplifier circuit 72 is connected to at least one of the reception signal paths of BandD, BandE, and BandF belonging to the low band group. The switch circuit 63 switches between connections between the transmission amplifier circuit 81 and transmission signal paths in a manner in which the transmission amplifier circuit 81 is connected to at least one of the transmission signal paths of BandA, BandB, and BandC belonging to the low band group. The switch circuit 64 switches between connections between the transmission amplifier circuit 82 and transmission signal paths in a manner in which the transmission amplifier circuit 82 is connected to at least one of the transmission signal paths of BandD, BandE, and BandF belonging to the low band group.

The switch circuit 65 switches between connections between the reception amplifier circuit 73 and reception signal paths in a manner in which the reception amplifier circuit 73 is connected to at least one of the reception signal paths of BandG, BandH, and BandJ belonging to the high band group. The switch circuit 66 switches between connections between the reception amplifier circuit 74 and reception signal paths in a manner in which the reception amplifier circuit 74 is connected to at least one of the reception signal paths of BandK, BandL, and BandM belonging to the high band group. The switch circuit 67 switches between connections between the transmission amplifier circuit 83 and transmission signal paths in a manner in which the transmission amplifier circuit 83 is connected to at least one of the transmission signal paths of BandG, BandH, and BandJ belonging to the high band group. The switch circuit 68 switches between connections between the transmission amplifier circuit 84 and transmission signal paths in a manner in which the transmission amplifier circuit 84 is connected to at least one of the transmission signal paths of BandK, BandL, and BandM belonging to the high band group.

The RF-signal processing circuit 95L processes radio-frequency reception signals that are inputted from the antenna element 10 via the reception signal paths of the low band group with, for example, a down-converter to generate reception signals and outputs the reception signals to the baseband signal processing circuit 96. The RF-signal processing circuit 95L processes a transmission signal that is inputted from the baseband signal processing circuit 96 with, for example, an up-converter to generate radio-frequency transmission signals and outputs the radio-frequency transmission signals to the transmission amplifier circuits 81 and 82 of the low band group.

The RF-signal processing circuit 95H processes radio-frequency reception signals that are inputted from the antenna element 10 via the reception signal paths of the high band group with, for example, a down-converter to generate reception signals and outputs the reception signals to the baseband signal processing circuit 96. The RF-signal processing circuit 95H processes a transmission signal that is inputted from the baseband signal processing circuit 96 with, for example an up-converter to generate radio-frequency transmission signals and outputs the radio-frequency transmission signals to the transmission amplifier circuits 83 and 84 of the high band group.

Examples of the RF-signal processing circuits 95L and 95H are RFICs (Radio Frequency Integrated Circuits).

The signals processed by the baseband signal processing circuit 96 are used, for example, as image signals for image display or as audio signals for telecommunication.

The control unit (e.g., a controller or processor) 90 controls connection of the switch circuits in accordance with the bands that are used. The control unit 90 controls the switch circuits 40L, 40H, and 61 to 68 on the basis of control signals representing the bands that are selectively used, and the control signals are supplied from, for example, the baseband signal processing circuit 96 or the RF-signal processing circuits 95L and 95H disposed at a subsequent stage.

The radio-frequency front-end circuit 1 may not include the control unit 90. The RF-signal processing circuits 95L and 95H or the baseband signal processing circuit 96 may include the control unit 90. In this case, the switch circuits 40L, 40H, and 61 to 68 are directly controlled by the RF-signal processing circuits 95L and 95H or the baseband signal processing circuit 96.

With the above structure, the radio-frequency front-end circuit 1 can transmit and receive radio-frequency signals in six bands belonging to the high band group and six bands belonging to the low band group. The radio-frequency front-end circuit 1 uses different bands at the same time to improve communication quality (for high-speed and stable communication), which is called a carrier aggregation method. For example, one of BandA, BandB, or BandC, one of BandD, BandE, or BandF, one of BandG, BandH, or BandJ, and one of BandK, BandL, or BandM can be used at the same time.

Impedance matching between the antenna element 10 and the signal paths is required for every combination of the antenna element 10 and the signal paths connected thereto. The required number of the impedance values of the impedance matching circuits 30L and 30H is equal to the number of the combinations. Accordingly, the impedance matching circuits 30L and 30H according to the embodiment can be tuned. The circuit configuration and operation of the impedance matching circuits 30L and 30H according to the embodiment will now be described in detail.

### 1.2 CIRCUIT CONFIGURATION OF IMPEDANCE MATCHING CIRCUITS 31 AND 32

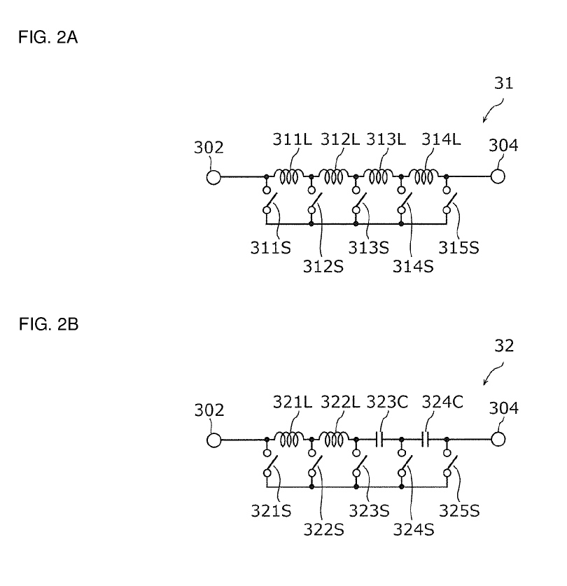

FIG. 2A is a circuit diagram of an impedance matching circuit 31 according to the embodiment. The impedance matching circuit 31 illustrated in FIG. 2A includes input-output terminals 302 and 304, inductors 311L, 312L, 313L, and 314L, and switches 311S, 312S, 313S, 314S, and 315S. The impedance matching circuit 31 is used as, for example, the impedance matching circuit 30L or 30H of the radio-frequency front-end circuit 1 illustrated in FIG. 1. In the case where the impedance matching circuit 31 is used as the impedance matching circuit 30L, the input-output terminal 302 is connected to the diplexer 20, and the input-output terminal 304 is connected to the switch circuit 40L. In the case where the impedance matching circuit 31 is used as the impedance matching circuit 30H, the input-output terminal 302 is connected to the diplexer 20, and the input-output terminal 304 is connected to the switch circuit 40H.

The inductors 311L (first inductor), 312L (second inductor), 313L, and 314L are connected in this order in series on a path connecting the input-output terminal 302 and the input-output terminal 304 to each other.

The switch 311S is a first switch that includes a first terminal and a second terminal and that switches between connection and disconnection between the first terminal and the second terminal. The first terminal is connected to an end of the inductor 311L. The switch 312S is a second switch that includes a third terminal and a fourth terminal and that switches between connection and disconnection between the third terminal and the fourth terminal. The third terminal is connected to a connection point of the other end of the inductor 311L and an end of the inductor 312L. The switch 313S is a third switch that includes a fifth terminal and a sixth terminal and that switches between connection and disconnection between the fifth terminal and the sixth terminal. The fifth terminal is connected to a connection point of the other end of the inductor 312L and an end of the inductor 313L. The second terminal, the fourth terminal, and the sixth terminal are connected to each other. The switch 314S includes two terminals, one of which is connected to a connection point of the other end of the inductor 313L and an end of the inductor 314L, and switches between connection and disconnection between the terminals. The other terminal of the switch 314S is connected to the second terminal, the fourth terminal, and the sixth terminal. The switch 315S includes two terminals, one of which is connected to the other end of the inductor 314L, and switches between connection and disconnection between the terminals. The other terminal of the switch 315S is connected to the second terminal, the fourth terminal, and the sixth terminal.

FIG. 2B is a circuit diagram of an impedance matching circuit 32 according to a first modification to the embodiment. The impedance matching circuit 32 illustrated in FIG. 2B includes the input-output terminals 302 and 304, inductors 321L (first inductor) and 322L (second inductor), capacitors 323C and 324C, and switches 321S (first switch), 322S (second switch), 323S (third switch), 324S (fourth switch), and 325S (fourth switch). The inductors 313L and 314L of the impedance matching circuit 31 are replaced with the capacitors 323C and 324C of the impedance matching circuit 32.

The inductors 321L (first inductor) and 322L (second inductor), capacitors 323C and 324C are connected in this order in series on the path connecting the input-output terminal 302 and the input-output terminal 304 to each other.

The switches 321S to 325S of the impedance matching circuit 32 are connected in the same manner as the switches 311S to 315S of the impedance matching circuit 31, and a description thereof is omitted.

In the impedance matching circuit 31 according to the embodiment and the impedance matching circuit 32 according to the first modification, the two or more inductors are connected in series between the input-output terminals, and an end of each switch is connected to the corresponding terminal of the two or more inductors, and the other ends of the switches are connected to each other.

### 1.3 CIRCUIT OPERATION OF IMPEDANCE MATCHING CIRCUITS 31 AND 32

The circuit operation of the impedance matching circuits 31 and 32 will now be described.

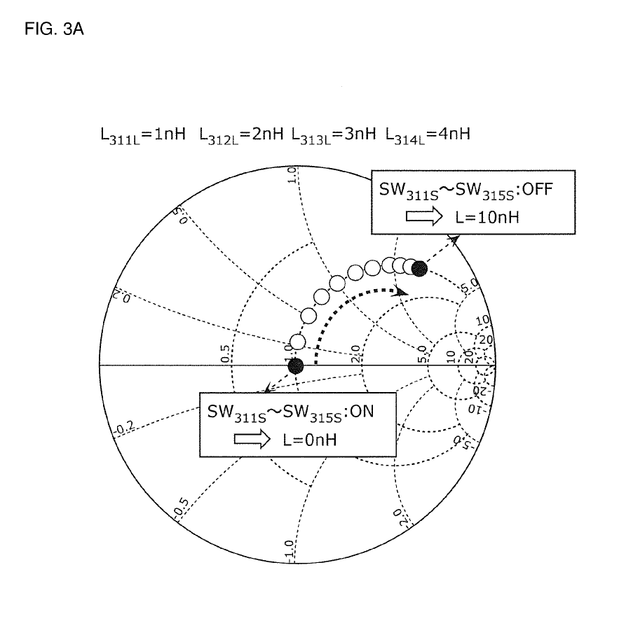

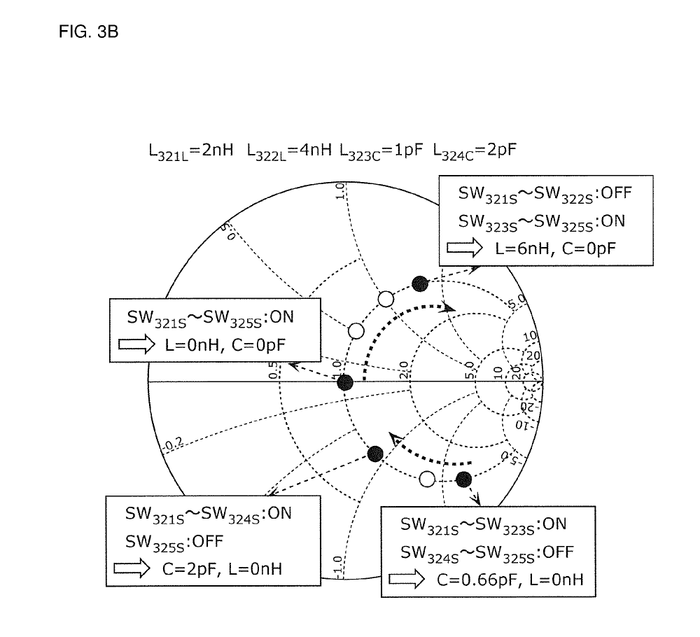

FIG. 3A illustrates a Smith chart indicating variation in the impedance of the impedance matching circuit 31 according to the embodiment. Here, the inductance values of the inductors 311L to 314L are determined to be 1 nH (L311L), 2 nH (L312L), 3 nH (L313L), and 4 nH (L314L). The inductance values may be determined in accordance with the required range of the inductance value of the impedance matching circuit 31. For example, the absolute values of the inductance values may be 1 nH (L311L), 2 nH (L312L), 4 nH (L313L), and 8 nH (L314L), or each inductance value may be increased to two times of another value with logarithms.

In FIG. 2A, the inductance value of the impedance matching circuit 31 can be changed with high precision by connecting or disconnecting the switches 311S to 315S separately. More specifically, all of the switches 311S to 315S are left in the connection state to set the inductance value of the impedance matching circuit 31 to the minimum value (0 nH), and all of the switches 311S to 315S are left in the disconnection state to set the inductance value (serial addition) of the impedance matching circuit 31 to the maximum value (10 nH). The difference between the minimum value and the maximum value is made variable. This enables the inductance value to be minutely changed at 1 nH steps.

The Smith chart in FIG. 3A indicates variation in the impedance of the impedance matching circuit 31 that is obtained by controlling connection or disconnection of the switches 311S to 315S separately as described above. The reactance of the impedance matching circuit 31 can be changed by changing the above inductance value.

FIG. 3B illustrates a Smith chart indicating variation in the impedance of the impedance matching circuit 32 according to the first modification to the embodiment. Here, the inductance values of the inductors 321L and 322L are determined to be 2 nH (L321L) and 4 nH (L322L). The capacitance values of the capacitors 323C and 324C are determined to be 1 pF (C323C) and 2 pF (L324C). That is, the absolute values of each inductance value and each capacitance value are increased to about two times of the other inductance value and the other capacitance value.

In FIG. 2B, the inductance value and capacitance value of the impedance matching circuit 32 can be changed with high precision by connecting or disconnecting the switches 321S to 325S separately. More specifically, all of the switches 321S to 325S are left in the connection state to set the combined inductance value and combined capacitance value of the impedance matching circuit 32 to the minimum values (0 nH and 0 pF). The switches 321S to 322S are left in the disconnection state, and the switches 323S to 325S are left in the connection state to set the combined inductance value of the impedance matching circuit 32 to the maximum value (6 nH) and set the combined capacitance value thereof to the minimum value (0 pF). The switches 321S to 323S are left in the connection state, and the switches 324S to 325S are left in the disconnection state to set the combined inductance value of the impedance matching circuit 32 to the minimum value (0 nH) and set the combined capacitance value thereof to 0.66 pF. The switches 321S to 324S are left in the connection state, and the switch 325S is left in the disconnection state to set the combined inductance value of the impedance matching circuit 32 to the minimum value (0 nH) and set the combined capacitance value thereof to 2 pF.

The Smith chart in FIG. 3B indicates variation in the impedance of the impedance matching circuit 32 that is obtained by controlling connection or disconnection of the switches 311S to 315S separately as described above. The reactance of the impedance matching circuit 32 can be changed by changing the above inductance value and the above capacitance value. Unlike the impedance matching circuit 31, the reactance changes not only in an inductive region but also in a capacitive region. That is, the impedance matching circuit 32 according to the present modification can make the range of the variable impedance wider than that of the impedance matching circuit 31 by adding the capacitors that are connected in series to the inductors that are connected in series.

In the case where the state of the impedance of an impedance matching circuit is changed in accordance with the combinations of the selectively connected signal paths, the required number of the inductance values of the impedance matching circuit is equal to the number of the combinations. For this reason, the existing technique needs inductors that correspond to the required inductance values. However, the larger the inductance values, the larger the size of the inductors, and the larger the number of the inductance values, the larger the size of the impedance matching circuit. From this perspective, the larger the number of the bands, the larger the size of the circuit, for example, in the case where a multi-band front-end circuit of a cellular phone is equipped with an impedance matching circuit.

The impedance matching circuits 31 and 32 according to the embodiment, however, can select four inductance values of 0, L1, L2, and (L1+L2) with the two inductors when the switches that are connected to the terminals of the two or more inductors that are connected in series are switched on (connection) or off (disconnection), for example, to set the inductance value of the first inductor to L1 and the inductance value of the second inductor to L2. That is, there is no need for a large inductor having an inductance value of (L1+L2), and the two inductors having inductance values smaller than (L1+L2) enable the inductance values to be selected stepwise from 0 to (L1+L2). In the case where three inductors (there is no need for the inductors when each inductance value is 0) correspond to four inductance values of 0, L1, L2, and (L1+L2), the required number of the inductance values is 2×(L1+L2) in total. This enables the range of the variable inductance values to be wider than the range of inductance values defined within the maximum value and minimum value of the inductance values of the inductors and enables the inductance values to be changed at narrower steps. Accordingly, impedance matching can be achieved even when the size of the circuit is decreased and the impedances of the radio-frequency circuits that are connected to the input-output terminals change.

### 1.4 CONFIGURATION OF IMPEDANCE MATCHING CIRCUIT

An example of the configuration of the impedance matching circuit 31 according to the embodiment will now be described.

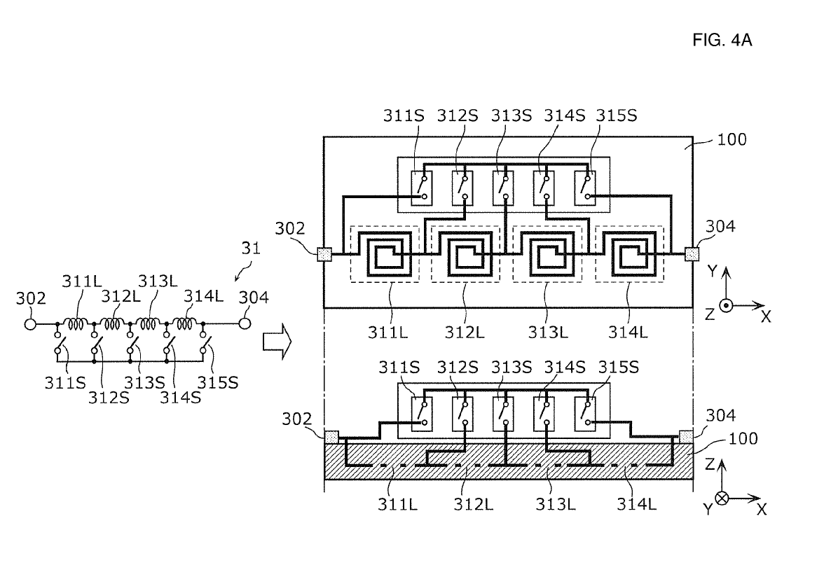

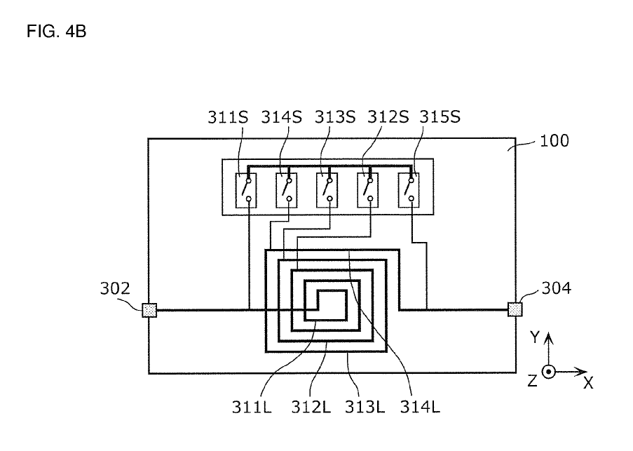

FIG. 4A illustrates a first example of the configuration of the impedance matching circuit 31 according to the embodiment. On the right-hand side in FIG. 4A, a plan view (upper side) and sectional view (lower side) of the impedance matching circuit 31 are illustrated. As illustrated in FIG. 4A, the impedance matching circuit 31 further includes a circuit board 100 for mounting the inductors and the switches. The inductors 311L to 314L are formed of spiral, flat coil patterns that are contained in the circuit board 100. The coil patterns corresponding to the respective inductors 311L to 314L are formed in the same layer.

The coil patterns of the inductors 311L to 314L are not limited to the pattern shape illustrated in FIG. 4A. The coil patterns may be spiral coil patterns that are formed across layers that form the circuit board 100 or may be coil patterns that are formed in the direction perpendicular to the main surfaces of the substrate. The number of turns of the coil patterns is not limited. The coil patterns may not be formed in the same layer but may be formed in different layers. The coil patterns may overlap in a plan view of the circuit board 100.

FIG. 4B illustrates a second example of the configuration of the impedance matching circuit 31 according to the embodiment. As illustrated in FIG. 4B, each of the inductors 311L to 314L is formed of a part of a spiral, flat coil pattern that is contained in the circuit board 100.

With the circuit configuration of the impedance matching circuit 31 according to the embodiment, the inductors having a total inductance value smaller than that according to the existing technique can ensure the desired range of the variable inductance. Accordingly, in the case of the configurations of the inductors illustrated in FIG. 4A and FIG. 4B, the area of the coil patterns or the number of stacked layers thereof can be decreased. Consequently, the size of the circuit board 100 can be decreased.

As illustrated in the sectional view in FIG. 4A, the switches 311S to 315S are mounted on a main surface of the circuit board 100. This enables the area of the impedance matching circuit 31 to be decreased because the switches 311S to 315S are stacked on the inductors 311L to 314L.

The switches 311S to 315S may be diode switches or FET (Field Effect Transistor) switches composed of gallium arsenide (GaAs) or a CMOS (Complementary Metal Oxide Semiconductor). This enables the size and cost of the impedance matching circuit 31 to be decreased.

The configuration of the impedance matching circuit 31 illustrated in FIG. 4A and FIG. 4B is also used as the configuration of the impedance matching circuit 32 according to the first modification. In this case, the capacitors 323C and 324C may be contained in the circuit board 100 together with the inductors 321L and 322L or may be disposed on a main surface of the circuit board 100.

### 1.5 CIRCUIT CONFIGURATION OF IMPEDANCE MATCHING CIRCUITS 33 AND 34

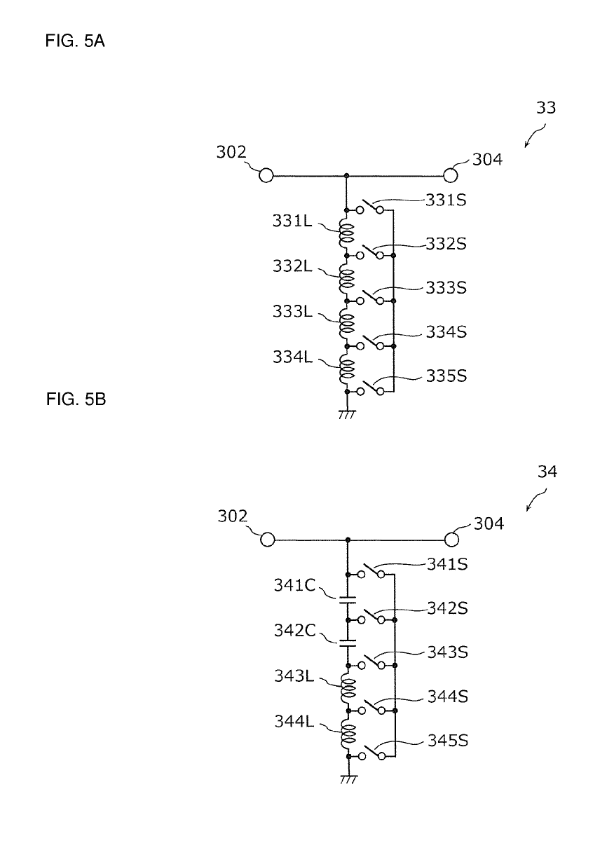

FIG. 5A is a circuit diagram of an impedance matching circuit 33 according to a second modification to the embodiment. The impedance matching circuit 33 illustrated in FIG. 5A differs from the impedance matching circuit 31 according to the embodiment in that the inductors are connected in series at positions different from those in the impedance matching circuit 31. Differences between the impedance matching circuit 33 according to the second modification and the impedance matching circuit 31 according to the embodiment will now be mainly described, and a description of the same matter is omitted.

The impedance matching circuit 33 includes the input-output terminals 302 and 304, inductors 331L, 332L, 333L, and 334L, and switches 331S, 332S, 333S, 334S, and 335S.

The inductors 331L (first inductor), 332L (second inductor), 333L, and 334L are connected in this order in series between a path connecting the input-output terminal 302 and the input-output terminal 304 to each other and the ground terminal.

The inductors 331L to 334L and the switches 331S to 335S are connected in the same manner as the inductors 311L to 314L and the switches 311S to 315S in FIG. 2A.

FIG. 5B is a circuit diagram of an impedance matching circuit 34 according to a third modification to the embodiment. The impedance matching circuit 34 illustrated in FIG. 5B differs from the impedance matching circuit 32 according to the first modification in that the inductors and the capacitors are connected in series at positions different from those in the impedance matching circuit 32. Differences between the impedance matching circuit 34 according to the third modification and the impedance matching circuit 32 according to the first modification will now be mainly described, and a description of the same matter is omitted.

The impedance matching circuit 34 includes the input-output terminals 302 and 304, inductors 343L and 344L, capacitors 341C and 342C, and switches 341S, 342S, 343S, 344S, and 345S.

The capacitors 341C and 342C and the inductors 343L (first inductor) and 344L (second inductor) are connected in this order in series between the path connecting the input-output terminal 302 and the input-output terminal 304 to each other and the ground terminal.

The inductors 344L and 343L, the capacitors 342C and 341C, and the switches 345S to 341S are connected in the same manner as the inductors 321L and 322L, the capacitor 323C and 324C, and the switches 321S to 325S in FIG. 2B.

### 1.6 CIRCUIT OPERATION OF IMPEDANCE MATCHING CIRCUITS 33 AND 34

The circuit operation of the impedance matching circuits 33 and 34 will now be described.

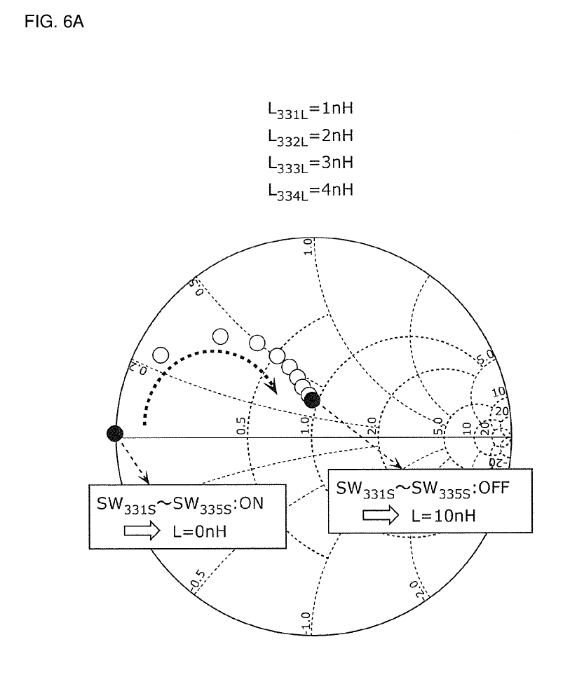

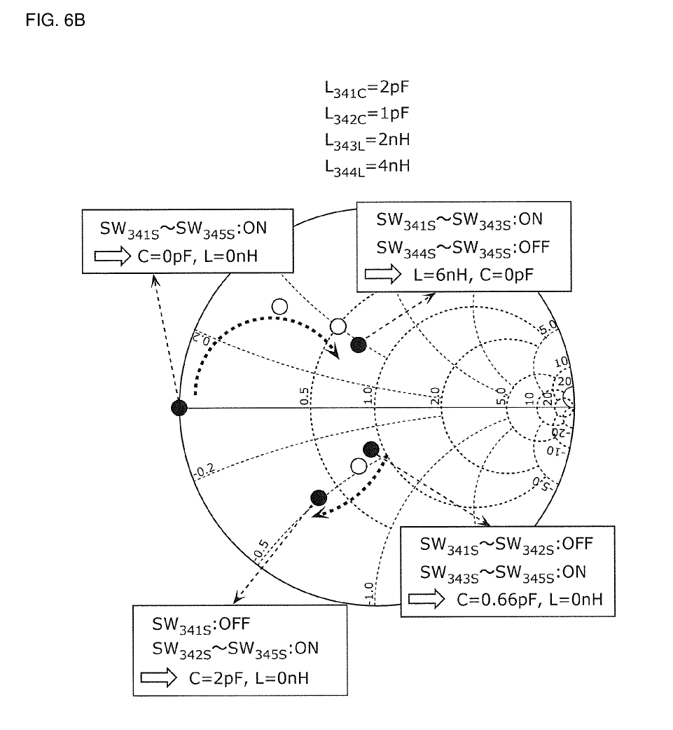

FIG. 6A illustrates a Smith chart indicating variation in the impedance of the impedance matching circuit 33 according to the second modification to the embodiment. Here, the inductance values of the inductors 331L to 334L are determined to be 1 nH (L331L), 2 nH (L332L), 3 nH (L333L), and 4 nH (L334L). The inductance values may be determined in accordance with the required range of the inductance value of the impedance matching circuit 33. For example, the absolute values of the inductance values may be 1 nH (L331L), 2 nH (L332L), 4 nH (L333L), and 8 nH (L334L), or each inductance value may be increased to two times of another value with logarithms.

In FIG. 5A, the inductance value of the impedance matching circuit 33 can be changed with high precision by connecting or disconnecting the switches 331S to 335S separately. More specifically, all of the switches 331S to 335S are left in the connection state to set the inductance value of the impedance matching circuit 33 to the minimum value (0 nH), and all of the switches 331S to 335S are left in the disconnection state to set the inductance value (serial addition) of the impedance matching circuit 33 to the maximum value (10 nH). The difference between the minimum value and the maximum value is made variable. This enables the inductance value to be minutely changed at 1 nH steps.

The Smith chart in FIG. 6A indicates variation in the impedance of the impedance matching circuit 33 that is obtained by controlling connection or disconnection of the switches 331S to 335S separately as described above. Susceptance in the admittance of the impedance matching circuit 33 can be changed by changing the above inductance value.

FIG. 6B illustrates a Smith chart indicating variation in the impedance of the impedance matching circuit 34 according to the third modification to the embodiment. Here, the inductance values of the inductors 343L and 344L are determined to be 2 nH (L343L) and 4 nH (L344L). The capacitance values of the capacitors 341C and 342C are determined to be 2 pF (C341C) and 1 pF (L342C). That is, the absolute values of each inductance value and each capacitance value are increased to about two times of the other inductance value and the other capacitance value.

In FIG. 5B, the inductance value and capacitance value of the impedance matching circuit 34 can be changed with high precision by connecting or disconnecting the switches 341S to 345S separately. More specifically, all of the switches 341S to 345S are left in the connection state to set the combined inductance value and combined capacitance value of the impedance matching circuit 34 to the minimum values (0 nH and 0 pF). The switches 344S to 345S are left in the disconnection state, and the switches 341S to 343S are left in the connection state to set the combined inductance value of the impedance matching circuit 34 to the maximum value (6 nH) and set the combined capacitance value thereof to the minimum value (0 pF). The switches 343S to 345S are left in the connection state, and the switches 341S to 342S are left in the disconnection state to set the combined inductance value of the impedance matching circuit 34 to the minimum value (0 nH) and set the combined capacitance value to 0.66 pF. The switches 342S to 345S are left in the connection state, and the switch 341S is left in the disconnection state to set the combined inductance value of the impedance matching circuit 34 to the minimum value (0 nH) and set the combined capacitance value thereof to 2 pF.

The Smith chart in FIG. 6B indicates variation in the impedance of the impedance matching circuit 34 that is obtained by controlling connection or disconnection of the switches 341S to 345S separately as described above. The susceptance in the admittance of the impedance matching circuit 34 can be changed by changing the above inductance value and the above capacitance value. Unlike the impedance matching circuit 33, the susceptance changes not only in the inductive region but also in the capacitive region. That is, the impedance matching circuit 34 according to the present modification can make the range of the variable impedance wider than that of the impedance matching circuit 33 by adding the capacitors that are connected in series to the inductors that are connected in series.

In the impedance matching circuits 33 and 34 according to the modifications to the embodiment, the switches that are connected to the terminals of the two or more inductors that are connected in series are switched on or off. This eliminates the need for a large inductor having the maximum value in the range of the variable inductance values, and the two inductors having inductance values smaller than the maximum value enable an inductance value ranging from the minimum value to the maximum value to be selected stepwise. This enables the range of the variable inductance values to be wider than the range of inductance values defined within the maximum value and minimum value of the inductance values of the inductors and enables the inductance values to be changed at narrow steps. Accordingly, impedance matching can be achieved even when the size of the circuit is decreased and the impedances of the radio-frequency circuits that are connected to the input-output terminals change.

### 1.7 CIRCUIT CONFIGURATION OF IMPEDANCE MATCHING CIRCUITS 35 AND 36

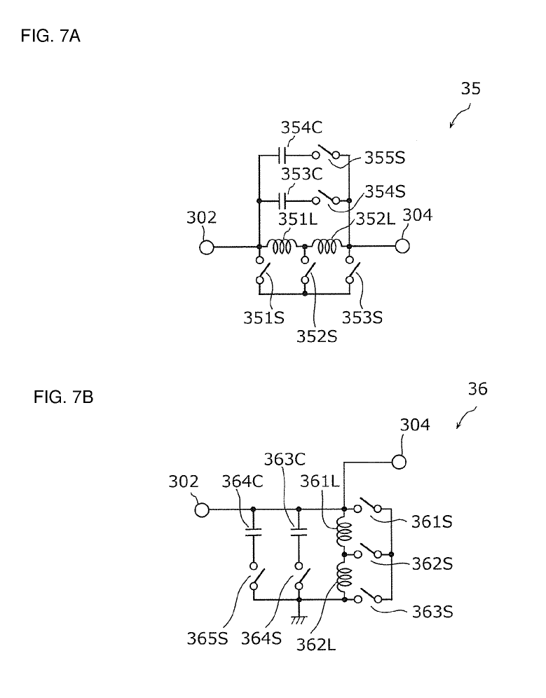

FIG. 7A is a circuit diagram of an impedance matching circuit 35 according to a fourth modification to the embodiment. The impedance matching circuit 35 illustrated in FIG. 7A includes the input-output terminals 302 and 304, inductors 351L and 352L, capacitors 353C and 354C, and switches 351S, 352S, 353S, 354S, and 355S.

The inductors 351L (first inductor) and 352L (second inductor) are connected in this order in series on the path connecting the input-output terminal 302 and the input-output terminal 304 to each other.

A series-connection circuit of the inductors 351L and 352L, a series-connection circuit of the capacitor 353C and the switch 354S (fourth switch), and a series-connection circuit of the capacitor 354C and the switch 355S (fourth switch) are connected in parallel between the input-output terminal 302 and the input-output terminal 304.

The switches 351S to 353S of the impedance matching circuit 35 are connected in the same manner as the switches 311S to 313S of the impedance matching circuit 31, and a description thereof is omitted.

A first terminal of the inductor 351L, a terminal of the capacitor 353C, and a terminal of the capacitor 354C are connected to the input-output terminal 302.

The switch 354S includes two terminals, one of which is connected to the other end of the capacitor 353C and the other of which is connected to the fourth terminal of the inductor 352L and the input-output terminal 304. The switch 355S includes two terminals, one of which is connected to the other end of the capacitor 354C and the other of which is connected to the fourth terminal of the inductor 352L and the input-output terminal 304.

FIG. 7B is a circuit diagram of an impedance matching circuit 36 according to a fifth modification to the embodiment. The impedance matching circuit 36 illustrated in FIG. 7B includes the input-output terminals 302 and 304, inductors 361L and 362L, capacitors 363C and 364C, and switches 361S, 362S, 363S, 364S, and 365S.

The inductors 361L (first inductor) and 362L (second inductor) are connected in this order in series between the path connecting the input-output terminal 302 and the input-output terminal 304 to each other and the ground terminal.

A series-connection circuit of the inductors 361L and 362L, a series-connection circuit of the capacitor 363C and the switch 364S (fourth switch), and a series-connection circuit of the capacitor 364C and the switch 365S (fourth switch) are connected in parallel between a path connecting the input-output terminal 302 and the input-output terminal 304 to each other and the ground terminal.

The switches 361S to 363S of the impedance matching circuit 36 are connected in the same manner as the switches 331S to 333S of the impedance matching circuit 33, and a description thereof is omitted.

A first terminal of the inductor 361L, a terminal of the capacitor 363C, and a terminal of the capacitor 364C are connected to the input-output terminals 302 and 304.

The switch 364S includes two terminals, one of which is connected to the other end of the capacitor 363C and the other of which is connected to the fourth terminal of the inductor 362L and the ground terminal. The switch 365S includes two terminals, one of which is connected to the other end of the capacitor 364C and the other of which is connected to the fourth terminal of the inductor 362L and the ground terminal.

### 1.8 CIRCUIT OPERATION OF IMPEDANCE MATCHING CIRCUITS 35 AND 36

The circuit operation of the impedance matching circuits 35 and 36 will now be described.

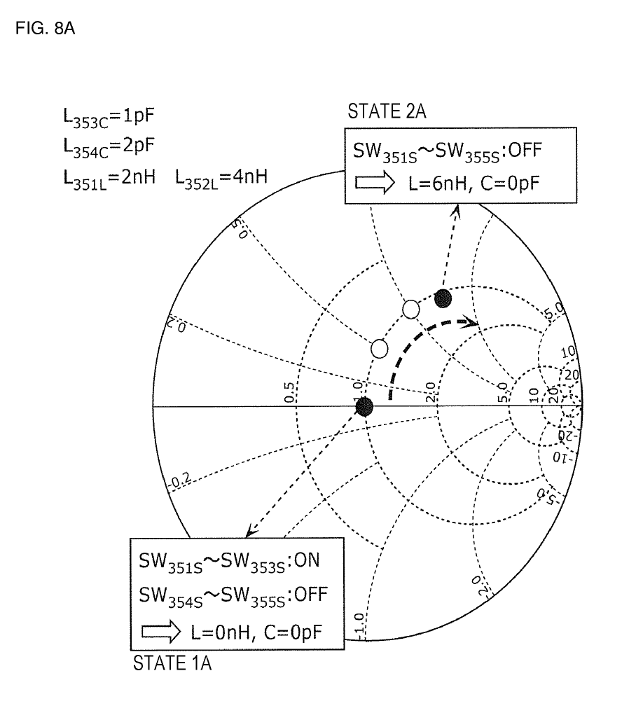

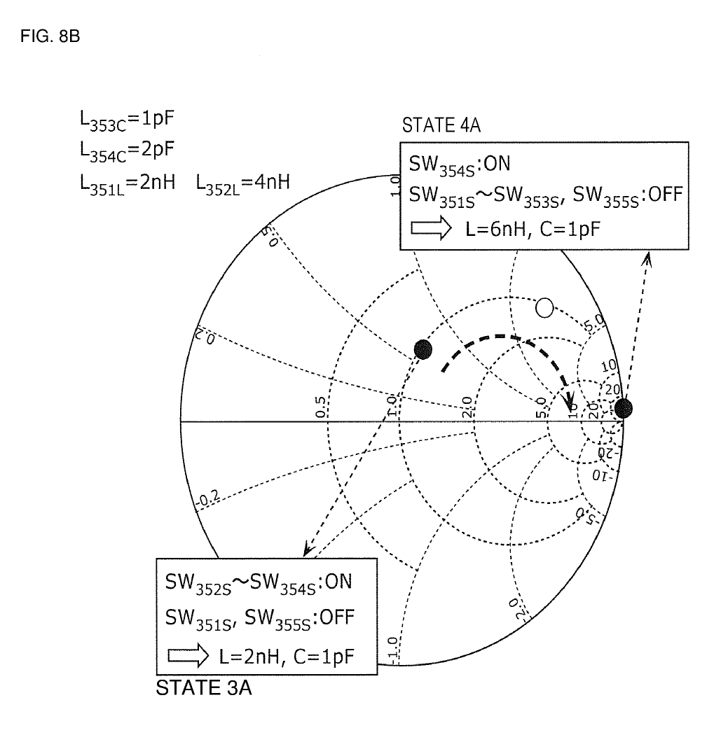

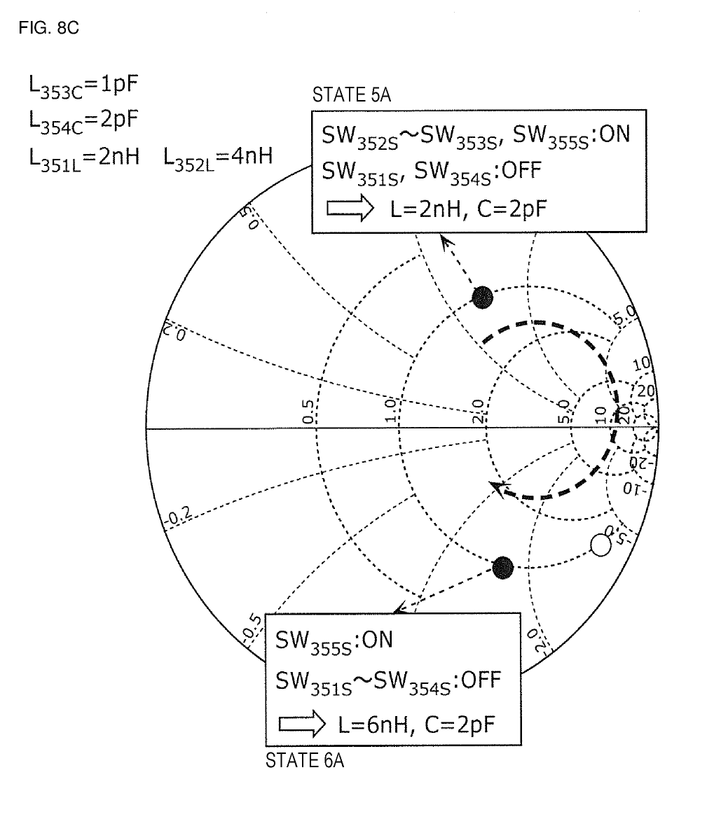

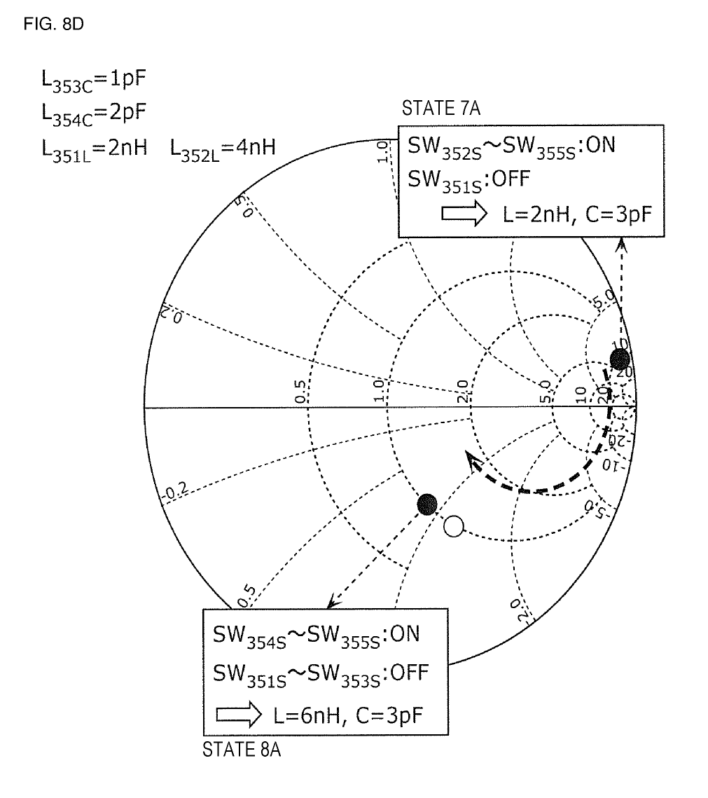

FIG. 8A, FIG. 8B, FIG. 8C, and FIG. 8D illustrate Smith charts indicating variation in the impedance of the impedance matching circuit 35 according to the fourth modification to the embodiment. FIG. 8A to FIG. 8D illustrate the variation in the impedance in the cases where the combined capacitance value of the impedance matching circuit 35 is 0 pF, 1 pF, 2 pF, or 3 pF. Here, the inductance values of the inductor 351L and 352L are determined to be 2 nH (L351L) and 4 nH (L352L). The capacitance values of the capacitor 353C and 354C are determined to be 1 pF (C353C) and 2 pF (L354C). That is, the absolute values of each inductance value and each capacitance value are increased to about two times of the other inductance value and the other capacitance value.

In FIG. 7A, the switches 351S to 353S are left in the connection state to set the combined inductance value to the minimum value (0 nH), and the switches 354S to 355S are left in the disconnection state to set the combined capacitance value to the minimum value (0 pF) (state 1A). The switches 351S to 355S are left in the disconnection state to set the combined inductance value to 6 nH and set the combined capacitance value to the minimum value (0 pF) (state 2A).

The Smith chart in FIG. 8A indicates that the impedances from the state 1A to the state 2A can be minutely determined (in four steps) by controlling the switches 351S to 353S separately. The reactance of the impedance matching circuit 35 can be changed by changing the above inductance value in a state where the switches 354S and 355S are left in the disconnection state (state where the combined capacitance value is 0 pF).

Subsequently, in FIG. 7A, the switch 351S is left in the disconnection state and the switches 352S to 353S are left in the connection state to set the combined inductance value to 2 nH, and the switch 354S is left in the connection state and the switch 355S is left in the disconnection state to set the combined capacitance value to 1 pF (state 3A). The switches 351S to 353S are left in the disconnection state to set the combined inductance value to 6 nH, and the switch 354S is left in the connection state and the switch 355S is left in the disconnection state to set the combined capacitance value to 1 pF (state 4A).

The Smith chart in FIG. 8B indicates that the impedances from the state 3A to the state 4A can be minutely determined (in three steps) by controlling the switches 351S to 353S separately. The reactance of the impedance matching circuit 35 can be changed by changing the above inductance value in a state where the switch 354S is left in the connection state and the switch 355S is left in the disconnection state (state where the combined capacitance value is 1 pF).

Subsequently, in FIG. 7A, the switch 351S is left in the disconnection state and the switches 352S to 353S are left in the connection state to set the combined inductance value to 2 nH, and the switch 355S is left in the connection state and the switch 354S is left in the disconnection state to set the combined capacitance value to 2 pF (state 5A). The switches 351S to 353S are left in the disconnection state to set the combined inductance value to 6 nH, and the switch 355S is left in the connection state and the switch 354S is left in the disconnection state to set the combined capacitance value to 2 pF (state 6A).

The Smith chart in FIG. 8C indicates that the impedances from the state 5A to the state 6A can be minutely determined (in three steps) by controlling the switches 351S to 353S separately. The reactance of the impedance matching circuit 35 can be changed by changing the above inductance value in a state where the switch 355S is left in the connection state and the switch 354S is left in the disconnection state (state where the combined capacitance value is 2 pF).

Subsequently, in FIG. 7A, the switch 351S is left in the disconnection state and the switches 352S to 353S are left in the connection state to set the combined inductance value to 2 nH, and the switches 354S and 355S are left in the connection state to set the combined capacitance value to 3 pF (state 7A). The switches 351S to 353S are left in the disconnection state to set the combined inductance value to 6 nH, and the switches 354S and 355S are left in the connection state to set the combined capacitance value to 3 pF (state 8A).

The Smith chart in FIG. 8D indicates that the impedances from the state 7A to the state 8A can be minutely determined (in three steps) by controlling the switches 351S to 353S separately. The reactance of the impedance matching circuit 35 can be changed by changing the above inductance value in a state where the switches 354S and 355S are left in the connection state (state where the combined capacitance value is 3 pF).

As illustrated in FIG. 8A to FIG. 8D, the inductance value is changed in a state where the combined capacitance value of the impedance matching circuit 35 is made variable and is, for example, 0 pF, 1 pF, 2 pF or 3 pF. This enables the range of the variable reactance of the impedance matching circuit 35 to be changed. That is, unlike the impedance matching circuit 31, the degree of freedom of the range of the variable impedance of the impedance matching circuit 35 according to the present modification can be increased by adding the capacitors that are connected in parallel to the inductors that are connected in series, and the range in which the impedance is adjusted can be widened.

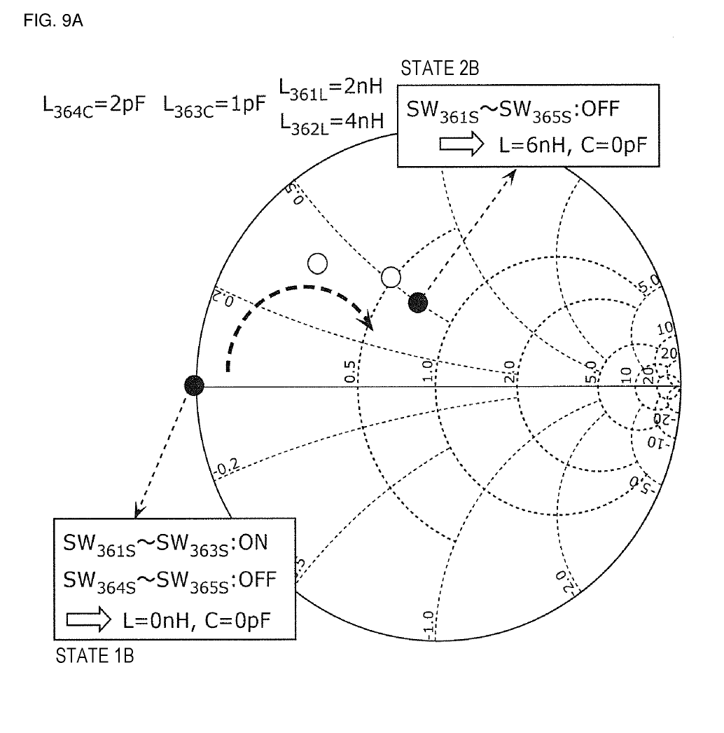

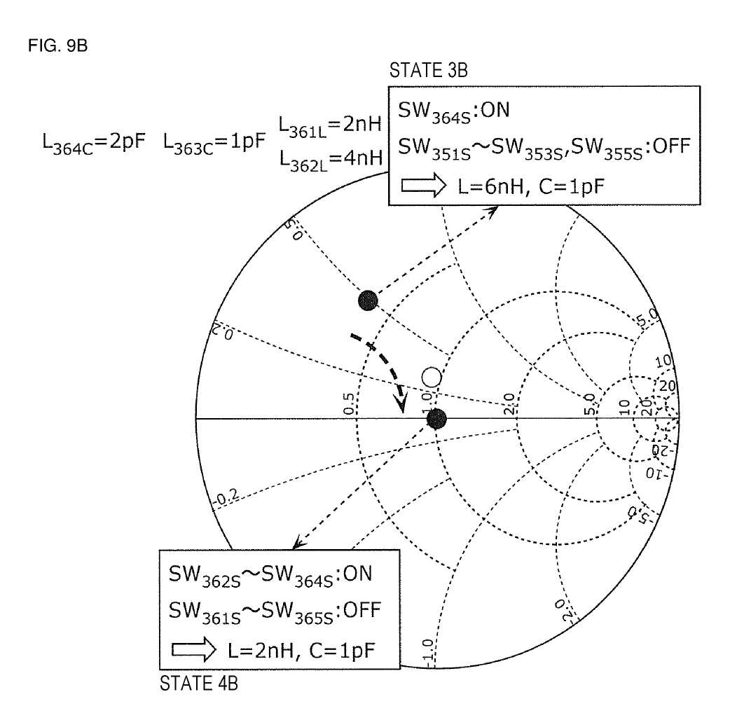

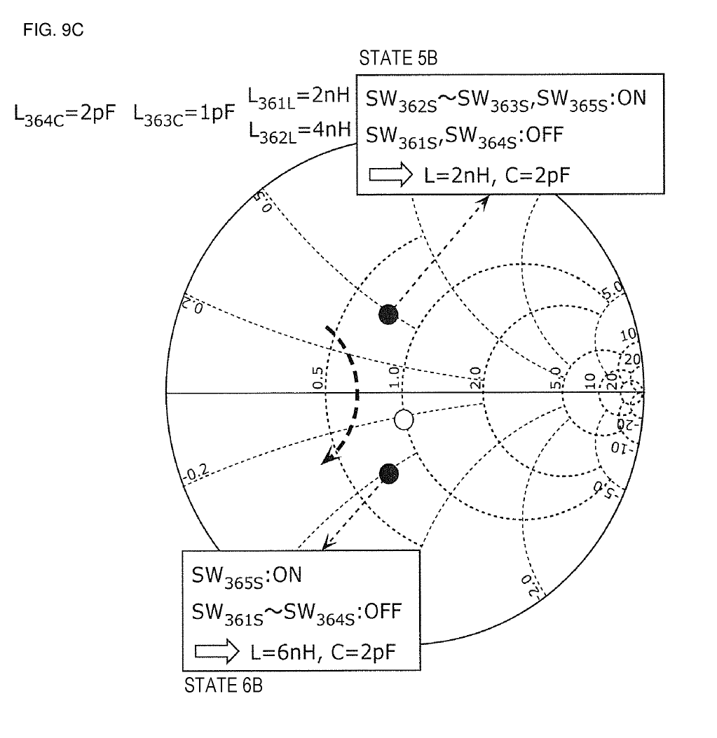

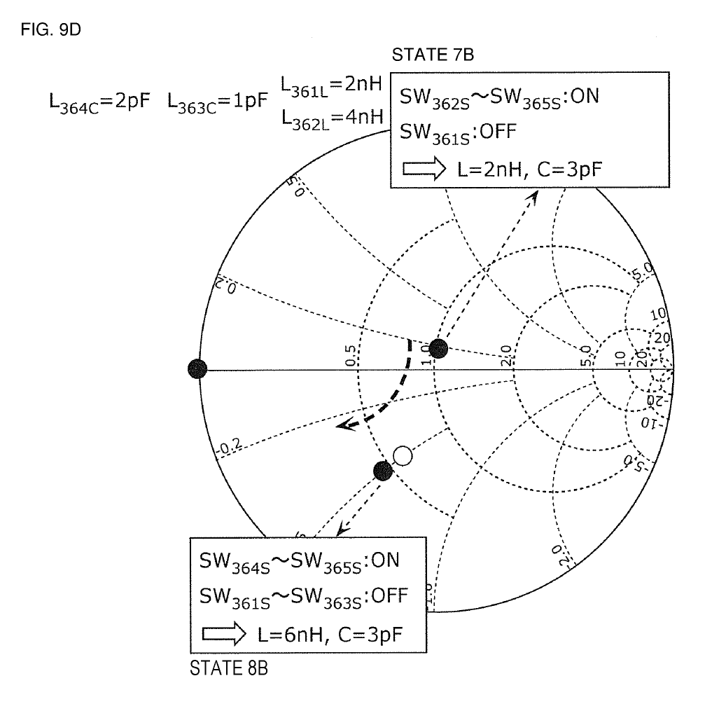

FIG. 9A, FIG. 9B, FIG. 9C, and FIG. 9D illustrate Smith charts indicating variation in the impedance of the impedance matching circuit 36 according to the fifth modification of the embodiment. FIG. 9A to FIG. 9D illustrate the variation in the impedance in the cases where the combined capacitance value of the impedance matching circuit 36 is 0 pF, 1 pF, 2 pF, or 3 pF. Here, the inductance values of the inductors 361L and 362L are determined to be 2 nH (L361L) and 4 nH (L362L). The capacitance values of the capacitors 363C and 364C are determined to be 1 pF (C363C) and 2 pF (L364C). That is, the absolute values of each inductance value and each capacitance value are increased to about two times of the other inductance value and the other capacitance value.

In FIG. 7B, the switches 361S to 363S are left in the connection state to set the combined inductance value to the minimum value (0 nH), and the switches 364S to 365S are left in the disconnection state to set the combined capacitance value to the minimum value (0 pF) (state 1B). The switches 361S to 365S are left in the disconnection state to set the combined inductance value to 6 nH and set the combined capacitance value to the minimum value (0 pF) (state 2B).

The Smith chart in FIG. 9A indicates that the impedances from the state 1B to the state 2B can be minutely determined (in four steps) by controlling the switches 361S to 363S separately. The susceptance in the admittance of the impedance matching circuit 36 can be changed by changing the above inductance value in a state where the switches 364S and 365S are left in the disconnection state (state where the combined capacitance value is 0 pF).

Subsequently, in FIG. 7B, the switch 361S is left in the disconnection state and the switches 362S to 363S are left in the connection state to set the combined inductance value to 2 nH, and the switch 364S is left in the connection state and the switch 365S is left in the disconnection state to set the combined capacitance value to 1 pF (state 3B). The switches 361S to 363S are left in the disconnection state to set the combined inductance value to 6 nH and the switch 364S is left in the connection state and the switch 365S is left in the disconnection state to set the combined capacitance value to 1 pF (state 4B).

The Smith chart in FIG. 9B indicates that the impedances from the state 3B to the state 4B can be minutely determined (in three steps) by controlling the switches 361S to 363S separately. The susceptance in the admittance of the impedance matching circuit 36 can be changed by changing the above inductance value in a state where the switch 364S is left in the connection state and the switch 365S is left in the disconnection state (state where the combined capacitance value is 1 pF).

Subsequently, in FIG. 7B, the switch 361S is left in the disconnection state and the switches 362S to 363S are left in the connection state to set the combined inductance value to 2 nH, and the switch 365S is left in the connection state and the switch 364S is left in the disconnection state to set the combined capacitance value to 2 pF (state 5B). The switches 361S to 363S are left in the disconnection state to set the combined inductance value to 6 nH, and the switch 365S is left in the connection state and the switch 364S is left in the disconnection state to set the combined capacitance value to 2 pF (state 6B).

The Smith chart in FIG. 9C indicates that the impedances from the state 5B to the state 6B can be minutely determined (in three steps) by controlling the switches 361S to 363S separately. The susceptance in the admittance of the impedance matching circuit 36 can be changed by changing the above inductance value in a state where the switch 365S is left in the connection state and the switch 364S is left in the disconnection state (state where the combined capacitance value is 2 pF).

Subsequently, in FIG. 7B, the switch 361S is left in the disconnection state and the switches 362S to 363S are left in the connection state to set the combined inductance value to 2 nH, and the switches 364S and 365S are left in the connection state to set the combined capacitance value to 3 pF (state 7B). The switches 361S to 363S are left in the disconnection state to set the combined inductance value to 6 nH, and the switches 364S and 365S are left in the connection state to set the combined capacitance value to 3 pF (state 8B).

The Smith chart in FIG. 9D indicates that the impedances from the state 7B to the state 8B can be minutely determined (in three steps) by controlling the switches 361S to 363S separately. The susceptance in the admittance of the impedance matching circuit 36 can be changed by changing the above inductance value in a state where the switches 364S and 365S are left in the connection state (state where the combined capacitance value is 3 pF).

As illustrated in FIG. 9A to FIG. 9D, the inductance value is changed in a state where the combined capacitance value of the impedance matching circuit 36 is made variable and is, for example, 0 pF, 1 pF, 2 pF or 3 pF. This enables the range of the variable susceptance of the impedance matching circuit 36 to be changed. That is, unlike the impedance matching circuit 32, the degree of freedom of the range of the variable impedance of the impedance matching circuit 36 according to the present modification can be increased by adding the capacitors that are connected in parallel to the inductors that are connected in series, and the range in which the impedance is adjusted can be widened.

### 1.9 CIRCUIT CONFIGURATION OF IMPEDANCE MATCHING CIRCUITS 37, 38, AND 39

The following description contains a composite circuit that includes a circuit that is connected in series to a path on which two or more inductors connect the input-output terminals to each other and a circuit that is connected in series between the path on which the two or more inductors connect the input-output terminals to each other and the ground terminal.

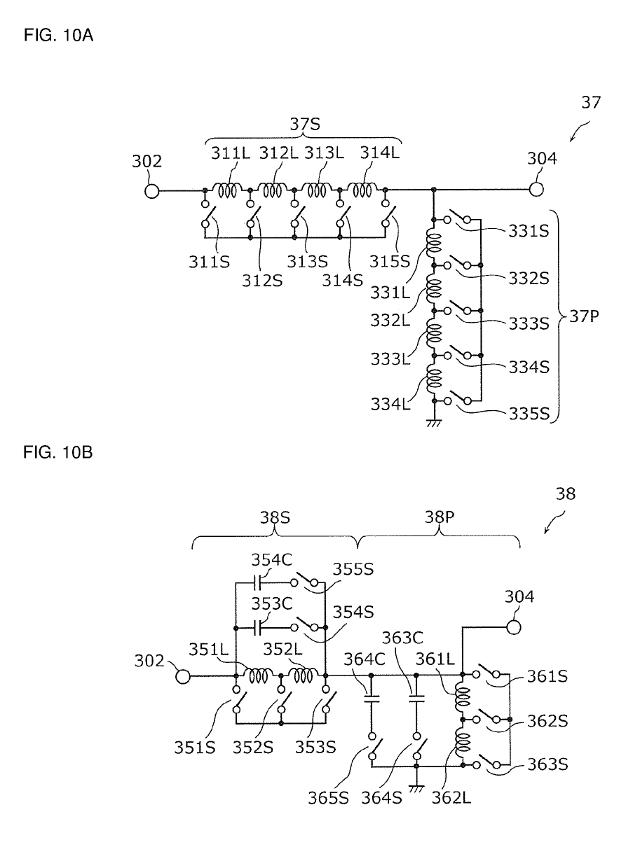

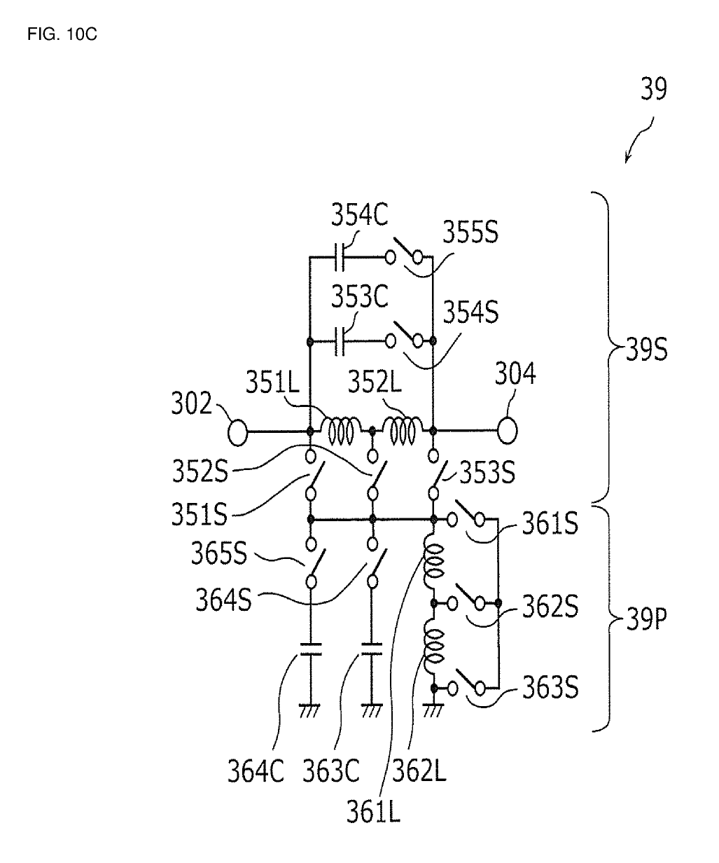

FIG. 10A is a circuit diagram of an impedance matching circuit 37 according to a sixth modification to the embodiment. The impedance matching circuit 37 illustrated in FIG. 10A includes the input-output terminals 302 and 304, a series variable matching unit 37S, and a parallel variable matching unit 37P.

The series variable matching unit 37S has the same circuit configuration as the impedance matching circuit 31 according to the embodiment and is disposed on a path connecting the input-output terminal 302 and the input-output terminal 304 to each other.

The parallel variable matching unit 37P has the same circuit configuration as the impedance matching circuit 33 according to the second modification and is disposed between the path connecting the input-output terminal 302 and the input-output terminal 304 to each other and the ground terminal.

The parallel variable matching unit 37P includes the inductors 331L, 332L, 333L, and 334L and the switches 331S, 332S, 333S, 334S, and 335S.

The inductors 331L (third inductor), 332L (fourth inductor), 333L, and 334L are connected in this order in series between the path connecting the input-output terminal 302 and the input-output terminal 304 to each other and the ground terminal.

The switch 331S is a fifth switch that includes a seventh terminal and an eighth terminal and that switches between connection and disconnection between the seventh terminal and the eighth terminal. The seventh terminal is connected to an end of the inductor 331L. The switch 332S is a sixth switch that includes a ninth terminal and a tenth terminal and that switches between connection and disconnection between the ninth terminal and the tenth terminal. The ninth terminal is connected to a connection point of the other end of the inductor 331L and an end of the inductor 332L. The switch 333S is a seventh switch that includes an eleventh terminal and a twelfth terminal and that switches between connection and disconnection between the eleventh terminal and the twelfth terminal. The eleventh terminal is connected to a connection point of the other end of the inductor 332L and an end of the inductor 333L. The eighth terminal, the tenth terminal, and the twelfth terminal are connected to each other. The switch 334S includes two terminals, one of which is connected to a connection point of the other end of the inductor 333L and an end of the inductor 334L and switches between connection and disconnection between the terminals. The other terminal of the switch 334S is connected to the eighth terminal, the tenth terminal, and the twelfth terminal. The switch 335S includes two terminals, one of which is connected to the other end of the inductor 334L and switches between connection and disconnection between the terminals. The other terminal of the switch 335S is connected to the eighth terminal, the tenth terminal, and the twelfth terminal.

FIG. 10B is a circuit diagram of an impedance matching circuit 38 according to a seventh modification to the embodiment. The impedance matching circuit 38 illustrated in FIG. 10B includes the input-output terminals 302 and 304, a series variable matching unit 38S, and a parallel variable matching unit 38P.

The series variable matching unit 38S has the same circuit configuration as the impedance matching circuit 35 according to the fourth modification and is disposed on the path connecting the input-output terminal 302 and the input-output terminal 304 to each other.

The parallel variable matching unit 38P has the same circuit configuration as the impedance matching circuit 36 according to the fifth modification and is disposed between the path connecting the input-output terminal 302 and the input-output terminal 304 to each other and the ground terminal.

The parallel variable matching unit 38P includes the inductors 361L and 362L, the capacitors 363C and 364C, and the switches 361S, 362S, 363S, 364S, and 365S.

The inductors 361L (third inductor) and 362L(fourth inductor) are connected in this order in series between the path connecting the input-output terminal 302 and the input-output terminal 304 to each other and the ground terminal.

The switch 361S is the fifth switch that includes the seventh terminal and the eighth terminal and that switches between connection and disconnection between the seventh terminal and the eighth terminal. The seventh terminal is connected to an end of the inductor 361L. The switch 362S is the sixth switch that includes the ninth terminal and the tenth terminal and that switches between connection and disconnection between the ninth terminal and the tenth terminal. The ninth terminal is connected to a connection point of the other end of the inductor 361L and an end of the inductor 362L. The switch 363S is the seventh switch that includes the eleventh terminal and the twelfth terminal and that switches between connection and disconnection between the eleventh terminal and the twelfth terminal. The eleventh terminal is connected to the other end of the inductor 362L and the ground terminal. The eighth terminal, the tenth terminal, and the twelfth terminal are connected to each other. The switch 364S (fourth switch) includes two terminals, one of which is connected to the other end of the capacitor 363C and the other of which is connected to the other end of the inductor 362L and the ground terminal. The switch 365S (fourth switch) includes two terminals, one of which is connected to the other end of the capacitor 364C and the other of which is connected to the other end of the inductor 362L and the ground terminal.

FIG. 10C is a circuit diagram of an impedance matching circuit 39 according to an eighth modification to the embodiment. The impedance matching circuit 39 illustrated in FIG. 10C includes the input-output terminals 302 and 304, a series variable matching unit 39S, and a parallel variable matching unit 39P.

The series variable matching unit 39S has the same circuit configuration as the impedance matching circuit 35 according to the fourth modification and is disposed on the path connecting the input-output terminal 302 and the input-output terminal 304 to each other.

The parallel variable matching unit 39P has the same circuit configuration as the impedance matching circuit 36 according to the fifth modification and is disposed between connection points at which the switches 351S to 353S of the series variable matching unit 39S are connected to each other and the ground terminals.

The parallel variable matching unit 39P includes the inductor 361L and 362L, the capacitors 363C and 364C, and the switches 361S, 362S, 363S, 364S, and 365S.

The inductors 361L (third inductor) and 362L (fourth inductor) are connected in this order in series between the second terminal of the switch 351S and one of the ground terminals, between the fourth terminal of the switch 352S and the ground terminal, and between the sixth terminal of the switch 353S and the ground terminal.

The switch 361S is the fifth switch that includes the seventh terminal and the eighth terminal and that switches between connection and disconnection between the seventh terminal and the eighth terminal. The seventh terminal is connected to an end of the inductor 361L. The switch 362S is the sixth switch that includes the ninth terminal and the tenth terminal and that switches between connection and disconnection between the ninth terminal and the tenth terminal. The ninth terminal is connected to a connection point of the other end of the inductor 361L and an end of the inductor 362L. The switch 363S is the seventh switch that includes the eleventh terminal and the twelfth terminal and that switches between connection and disconnection between the eleventh terminal and the twelfth terminal. The eleventh terminal is connected to the other end of the inductor 362L and the ground terminal. The eighth terminal, the tenth terminal, and the twelfth terminal are connected to each other. The switch 364S (fourth switch) includes two terminals, one of which is connected to the connection points at which the switches 351S, 352S, and 353S are connected to each other and the other of which is connected to an end of the capacitor 363C. The switch 365S (fourth switch) includes two terminals, one of which is connected to the connection points at which the switches 351S, 352S, and 353S are connected to each other and the other of which is connected to an end of the capacitor 364C. The other end of the capacitor 363C and the other end of the capacitor 364C are connected to the corresponding ground terminals.

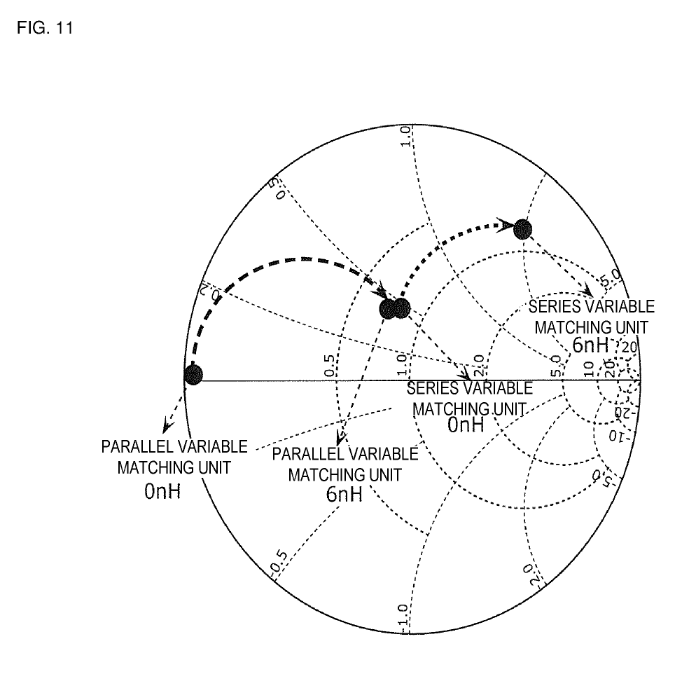

FIG. 11 illustrates a Smith chart indicating variation in the impedances of the impedance matching circuits 37 to 39 according to the sixth to eighth modifications to the embodiment. The Smith chart in FIG. 11 indicates that the impedances of the impedance matching circuits 37 to 39 according to the sixth to eighth modifications can be minutely determined (in plural steps) by controlling the switches separately.

The combined inductance value is changed in a state where the parallel variable matching units 37P, 38P, and 39P make the combined capacitance value variable. This enables the susceptance in the admittances of the impedance matching circuits 37 to 39 to be changed. The combined inductance value is changed in a state where the series variable matching units 37S, 38S, and 39S make the combined capacitance value variable. This enables the reactance of the impedance matching circuits 37 to 39 to be changed. That is, the impedance matching circuits 37 to 39 according to the sixth to eighth modifications, which include the series variable matching units and the parallel variable matching units, can match the real part and imaginary part of the impedance unlike the impedance matching circuits 31 to 36, and the accuracy of impedance matching can be improved more than the impedance matching circuits 31 to 36. The degree of freedom of the range of the variable impedance can be further increased, and the range in which the impedance is adjusted can be further widened.

### 1.10 EXAMPLE

An example of the impedance matching circuit according to the embodiment, which is used as the radio-frequency front-end circuit 1 illustrated in FIG. 1, will now be described.

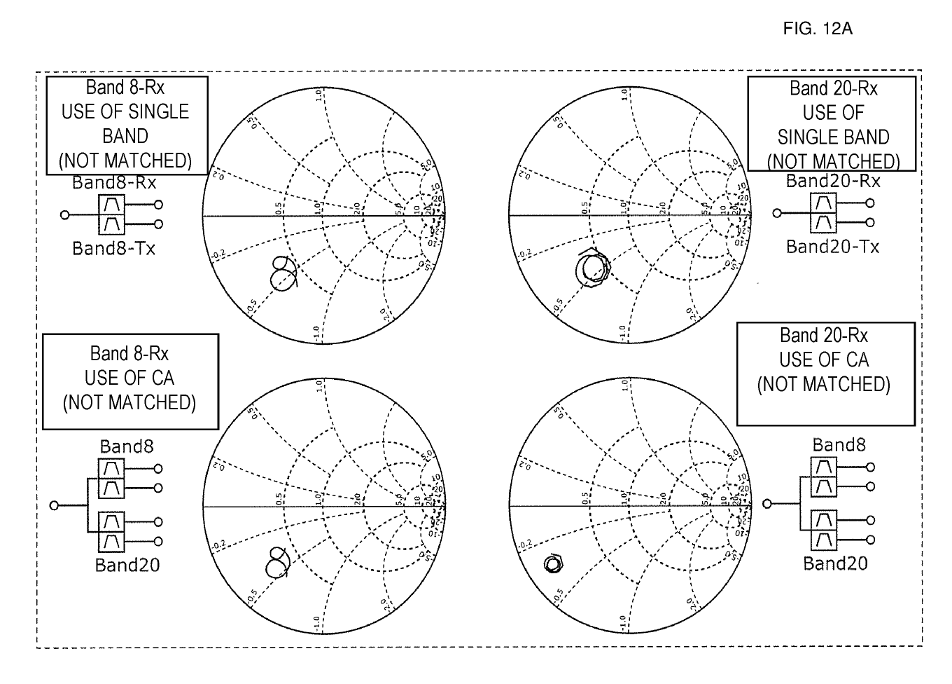

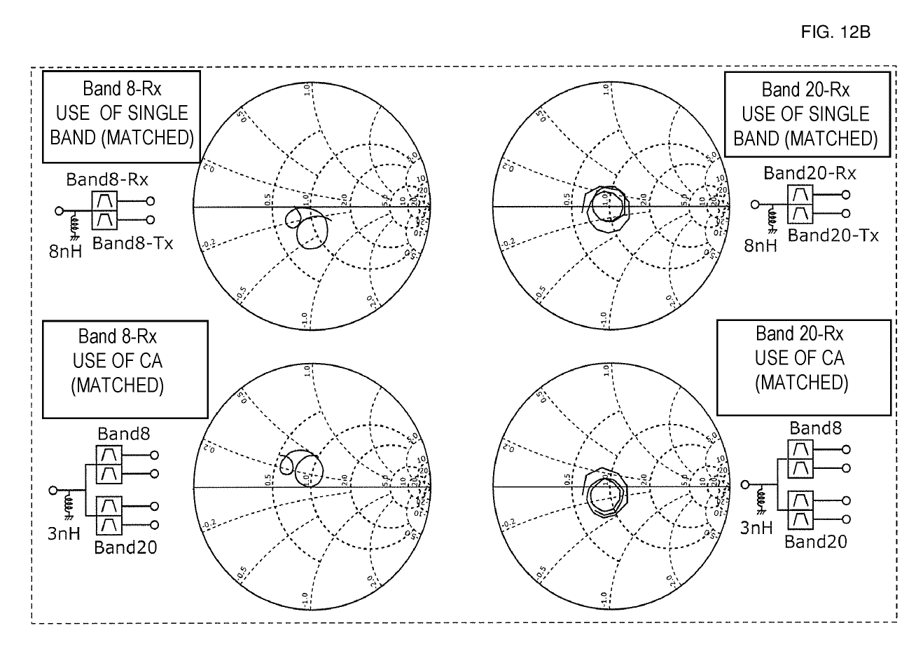

FIG. 12A illustrates Smith charts indicating states of impedance matching in Band8 and Band20 in a comparative example. FIG. 12B illustrates Smith charts indicating states of impedance matching in Band8 and Band20 in an example.

Here, the bands used in the radio-frequency front-end circuit 1 are Band8 (a transmission band of 880 to 915 MHz and a reception band of 925 to 960 MHz) and Band20 (a transmission band of 832 to 862 MHz and a reception band of 791 to 821 MHz) belonging to the low band group. The charts indicate two cases: a case where each of Band8 and Band20 is used as a single band, and a case where Band8 and Band20 are used at the same time (carrier aggregation).

FIG. 12A illustrates states of impedance matching in the case where the impedance matching circuit according to the embodiment is not used. As illustrated on the upper side in FIG. 12A, in the case where each of Band8 and Band20 is used as a single band, impedances when the duplexers in the bands are viewed from the antenna side have substantial differences from characteristic impedance (50Ω) and are capacitive. As illustrated on the lower side in FIG. 12A, in the case where Band8 and Band20 are used at the same time, the impedances when the duplexers in the bands are viewed from the antenna side have substantial differences from the characteristic impedance (50Ω) and are capacitive.

FIG. 12B illustrates states of impedance matching in the case where the impedance matching circuit according to the embodiment is used. In particular, the impedance matching circuit 33 (FIG. 5A) according to the second modification to the embodiment is used in the example.

As illustrated on the upper side in FIG. 12B, in the case where each of Band8 and Band20 is used as a single band, the impedances when the duplexers in the bands are viewed from the antenna side are substantially equal to the characteristic impedance (50Ω), and the impedances are matched. Here, the combined inductance value of the impedance matching circuit 33 is adjusted to 8 nH. More specifically, when the inductance value of the impedance matching circuit 33 is 1 nH (L331L), 2 nH (L332L), 3 nH (L333L), or 4 nH (L334L), the switches 332S and 333S are left in the connection state, and the switches 331S, 334S, and 335S are left in the disconnection state to set the combined inductance value (8 nH).

As illustrated on the lower side in FIG. 12B, in the case where Band8 and Band20 are used at the same time, the impedances when the duplexers in the bands are viewed from the antenna side are substantially equal to the characteristic impedance (50Ω), and the impedances are matched. Here, the combined inductance value of the impedance matching circuit 33 is adjusted to 3 nH. More specifically, when the inductance value of the impedance matching circuit 33 is 1 nH (L331L), 2 nH (L332L), 3 nH (L333L), or 4 nH (L334L), the switches 333S to 335S are left in the connection state, and the switches 331S and 332S are left in the disconnection state to set the combined inductance value (3 nH).

The use of the impedance matching circuit according to the embodiment, which has a simple and compact circuit configuration as described above, for the radio-frequency front-end circuit achieves flexible impedance matching with high precision even when a specific band of the bands is used as a single band or when the bands are used at the same time.

### Other Embodiments

The impedance matching circuits 31 to 39 and the radio-frequency front-end circuit 1 according to the embodiment and the modifications of the present disclosure are described above. According to the present disclosure, the impedance matching circuit and the radio-frequency front-end circuit are not limited to the embodiment and the modifications. The present disclosure includes another embodiment obtained by combining the features of the embodiment and the modifications, another modification modified from the embodiment by a person skilled in the art without departing from the spirit of the present disclosure, and various devices that contain the impedance matching circuit or the radio-frequency front-end circuit according to the present disclosure.

For example, the impedance matching circuits 31 to 39 may not be disposed between the diplexer 20 and the switch circuit 40L or 40H of the radio-frequency front-end circuit 1 illustrated in FIG. 1. It is only necessary for the impedance matching circuits 31 to 39 to be disposed between the radio-frequency circuits, provided that the impedance matching circuits 31 to 39 are circuits that change the impedances in accordance with two or more radio-frequency circuits selected from the radio-frequency circuits.

For example, any one of the impedance matching circuits 31 to 39 according to the embodiment may be disposed between one of the amplifier circuits and the corresponding switch circuit of the radio-frequency front-end circuit 1.

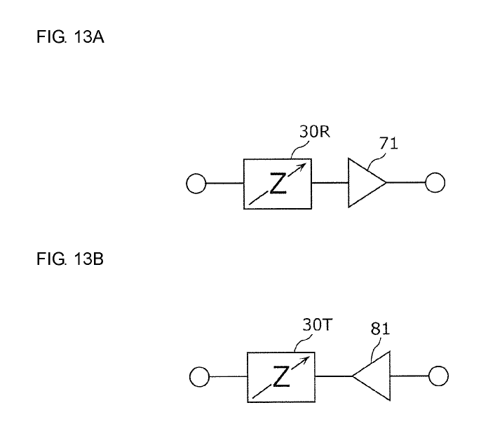

FIG. 13A illustrates a part of a radio-frequency front-end circuit according to a ninth modification. That is, the present disclosure includes a radio-frequency front-end circuit that includes the reception amplifier circuit 71 that amplifies the radio-frequency signals, an impedance matching circuit 30R that is connected to the reception amplifier circuit 71 and that corresponds to any one of the impedance matching circuits 31 to 39, filters (for BandA-Rx, BandB-Rx, and BandC-Rx) having different pass bands, and the switch circuit 61 that switches between connections between at least one of the filters and the impedance matching circuit 30R. The impedance matching circuit 30R may be disposed between the reception amplifier circuit 71 and the switch circuit 61, between the reception amplifier circuit 72 and the switch circuit 62, between the reception amplifier circuit 73 and the switch circuit 65, or between the reception amplifier circuit 74 and the switch circuit 66.

FIG. 13B illustrates a part of a radio-frequency front-end circuit according to a tenth modification. That is, the present disclosure includes a radio-frequency front-end circuit that includes the transmission amplifier circuit 81 that amplifies the radio-frequency signals, an impedance matching circuit 30T that is connected to the transmission amplifier circuit 81 and that corresponds to any one of the impedance matching circuits 31 to 39, filters (for BandA-Tx, BandB-Tx, and BandC-Tx) having different pass bands, and the switch circuit 63 that switches between connections between at least one of the filters and the impedance matching circuit 30T. The impedance matching circuit 30T may be disposed between the transmission amplifier circuit 81 and the switch circuit 63, between the transmission amplifier circuit 82 and the switch circuit 64, between the transmission amplifier circuit 83 and the switch circuit 67, or between the transmission amplifier circuit 84 and the switch circuit 68.

These enable the radio-frequency front-end circuits to be small and enable the impedances to be successfully matched even when the states of the connections between the filters and the amplifier circuits are changed.

The present disclosure is not limited to the above impedance matching circuits and the radio-frequency front-end circuits and includes a communication device that includes one of the impedance matching circuits or one of the radio-frequency front-end circuits.

That is, as illustrated in FIG. 1, the communication device 2 according to the present disclosure includes the radio-frequency front-end circuit 1 that includes any one of the impedance matching circuits 31 to 39, the control unit 90 that controls the states of the connections between the first switch, the second switch, and the third switch of the impedance matching circuit, and the RF-signal processing circuits 95L and 95H that process the radio-frequency signals. The control unit 90 may select a mode, on the basis of the frequency band that is selected, from (1) a first mode in which the first switch, the second switch, and the third switch are left in the connection state and an inductance component is minimized, (2) a second mode in which the first switch and the second switch are left in the connection state and the third switch is in the disconnection state, (3) a third mode in which the second switch and the third switch are left in the connection state and the first switch is in the disconnection state, and (4) a fourth mode in which the first switch, the second switch, and the third switch are left in the disconnection state and the inductance component is maximized.

This enables the communication device to be small and enables the impedances to be successfully matched in accordance with the selected frequency band.

According to the present disclosure, the control unit 90 may be an IC or LSI (Large Scale Integration), which is an integrated circuit. A technique of building the integrated circuit may be achieved by a dedicated circuit or a general-purpose processor. FPGA (Field Programmable Gate Array) that enables programing after the LSI is manufactured or a reconfigurable processor that can re-configurate connection or setting of a circuit cell in the LSI. In addition, another technique of building the integrated circuit that will be developed in replacement of the LSI by advanced semiconductor technology or another technique derived therefrom may be naturally used for an integrated function block.

In the impedance matching circuits according to the embodiment and the modifications, an inductor or a capacitor may be connected between the terminals such as the input-output terminals and the ground terminal, or another circuit element such as a resistance element other than the inductor and the capacitor may be added.

The present disclosure can be widely used as a small impedance matching circuit, a radio-frequency front-end circuit, or a communication device that can be used at a front end of a multi-band and multi-mode system for communication equipment such as a cellular phone.

1 radio-frequency front-end circuit

2 communication device

10 antenna element

20 diplexer

31, 32, 33, 34, 35, 36, 37, 38, 39, 30H, 30L, 30R, 30T impedance matching circuit

37P, 38P, 39P parallel variable matching unit

37S, 38S, 39S series variable matching unit

40H, 40L, 61, 62, 63, 64, 65, 66, 67, 68 switch circuit

50A, 50B, 50C, 50D, 50E, 50F, 50G, 50H, 50J, 50K, 50L, 50M duplexer

71, 72, 73, 74 reception amplifier circuit

81, 82, 83, 84 transmission amplifier circuit

90 control unit

95H, 95LRF signal processing circuit

96 baseband signal processing circuit

100 circuit board

302, 304 input-output terminal

311L, 312L, 313L, 314L, 321L, 322L, 331L, 332L, 333L, 334L, 343L, 344L, 351L, 352L, 361L, 362L inductor

311S, 312S, 313S, 314S, 315S, 321S, 322S, 323S, 324S, 325S, 331S, 332S, 333S, 334S, 335S, 341S, 342S, 343S, 344S, 345S, 351S, 352S, 353S, 354S, 355S, 361S, 362S, 363S, 364S, 365S switch

323C, 324C, 341C, 342C, 353C, 354C, 363C, 364C capacitor

1. An impedance matching circuit that is disposed between a plurality of radio-frequency circuits and that is configured to match impedances when two or more radio-frequency circuits of the plurality of radio-frequency circuits are connected, the impedance matching circuit comprising:
a first inductor and a second inductor that are connected in series;
a first switch having a first terminal and a second terminal, the first switch being configured to selectively connect the first terminal and the second terminal, wherein the first terminal is connected to a first end of the first inductor;
a second switch having a third terminal and a fourth terminal, the second switch being configured to selectively connect the third terminal and the fourth terminal, wherein the third terminal is connected to a node between a second end of the first inductor and a first end of the second inductor; and
a third switch having a fifth terminal and a sixth terminal, the third switch being configured to selectively connect the fifth terminal and the sixth terminal, wherein the fifth terminal is connected to a second end of the second inductor,
wherein the second terminal, the fourth terminal, and the sixth terminal are connected to each other.

2. The impedance matching circuit according to claim 1, further comprising:
a first input-output terminal and a second input-output terminal, the first and second input-output terminals being connected to the two or more radio-frequency circuits,
wherein the first inductor and the second inductor are connected in series between the first input-output terminal and the second input-output terminal.

3. The impedance matching circuit according to claim 1, further comprising:
a first input-output terminal and a second input-output terminal, the first and second input-output terminals being connected to the plurality of radio-frequency circuits,
wherein the first inductor and the second inductor are connected in series between a ground terminal and a path connecting the first input-output terminal and the second input-output terminal.

4. The impedance matching circuit according to claim 1, further comprising:
a capacitor connected to the first inductor or the second inductor; and
a fourth switch connected to the capacitor.

5. The impedance matching circuit according to claim 2, further comprising:
a capacitor connected to the first inductor or the second inductor; and
a fourth switch connected to the capacitor.

6. the impedance matching circuit according to claim 3, further comprising:
a capacitor connected to the first inductor or the second inductor; and
a fourth switch connected to the capacitor.

7. The impedance matching circuit according to claim 1, further comprising:
a first input-output terminal and a second input-output terminal, the first and second input-output terminals being connected to the two or more radio-frequency circuits;
a third inductor and a fourth inductor that are connected in series;
a fifth switch having a seventh terminal and an eighth terminal, the fifth switch being configured to selectively connect the seventh terminal and the eighth terminal, wherein the seventh terminal is connected to a first end of the third inductor;
a sixth switch having a ninth terminal and a tenth terminal, the sixth switch being configured to selectively connect the ninth terminal and the tenth terminal, wherein the ninth terminal is connected to a node between a second end of the third inductor and a first end of the fourth inductor; and
a seventh switch having an eleventh terminal and a twelfth terminal, the seventh switch being configured to selectively connect the eleventh terminal and the twelfth terminal, wherein the eleventh terminal is connected to a second end of the fourth inductor,
wherein the eighth terminal, the tenth terminal, and the twelfth terminal are connected to each other,
wherein the first inductor and the second inductor are connected in series between the first input-output terminal and the second input-output terminal, and
wherein the third inductor and the fourth inductor are connected in series between a ground terminal and a path connecting the first input-output terminal and the second input-output terminal.

8. The impedance matching circuit according to claim 7, further comprising:
a capacitor connected to the first inductor or the second inductor; and
a fourth switch connected to the capacitor.

9. The impedance matching circuit according to claim 1, further comprising:
a first input-output terminal and a second input-output terminal, the first and second input-output terminals being connected to the two or more radio-frequency circuits;
a third inductor and a fourth inductor that are connected in series;
a fifth switch having a seventh terminal and an eighth terminal, the fifth switch being configured to selectively connect the seventh terminal and the eighth terminal, wherein the seventh terminal is connected to a first end of the third inductor;
a sixth switch having a ninth terminal and a tenth terminal, the sixth switch being configured to selectively connect the ninth terminal and the tenth terminal, wherein the ninth terminal is connected to a node between a second end of the third inductor and a first end of the fourth inductor; and
a seventh switch having an eleventh terminal and a twelfth terminal, the seventh switch being configured to selectively connect the eleventh terminal and the twelfth terminal, wherein the eleventh terminal is connected to a second end of the fourth inductor,
wherein the eighth terminal, the tenth terminal, and the twelfth terminal are connected to each other,
wherein the first inductor and the second inductor are connected in series between the first input-output terminal and the second input-output terminal, and
wherein the third inductor and the fourth inductor are connected in series between the second terminal and a ground terminal.

10. The impedance matching circuit according to claim 9, further comprising:
a capacitor connected to the first inductor or the second inductor; and
a fourth switch connected to the capacitor.

11. The impedance matching circuit according to claim 1, wherein the first inductor and the second inductor are formed as a coil pattern in a circuit board.

12. Yhe impedance matching circuit according to claim 11, wherein the first switch, the second switch, and the third switch are mounted on a main surface of the circuit board.

13. The impedance matching circuit according to claim 1, wherein the first switch, the second switch, and the third switch are diode switches or field effect transistor (FET) switches composed of gallium arsenide (GaAs) or a complementary metal oxide semiconductor (CMOS).

14. A radio-frequency front-end circuit comprising:
the impedance matching circuit according to claim 1 connected to an antenna or a demultiplexer;
a plurality of filters, each of the plurality of filters having different pass bands; and
a switch circuit configured to selectively switch connection between at least one of the plurality of filters and the impedance matching circuit.

15. A radio-frequency front-end circuit comprising:
an amplifier circuit configured to amplify a radio-frequency signal;
the impedance matching circuit according to claim 1 connected to the amplifier circuit;
a plurality of filters, each of the plurality of filters having different pass bands; and
a switch circuit configured to selectively switch connection between at least one of the plurality of filters and the impedance matching circuit.

16. A communication device comprising:
the radio-frequency front-end circuit according to claim 14;
a controller configured to control states of connection of the first switch, the second switch, and the third switch; and
a RF-signal processing circuit configured to process a radio-frequency signal,
wherein the controller is configured to select a mode based on a frequency band of the radio-frequency signal, the mode being:
(1) a first mode in which the first switch, the second switch, and the third switch are closed, thereby minimizing an inductance component of the impedance matching circuit,
(2) a second mode in which the first switch and the second switch are closed and the third switch is open,
(3) a third mode in which the second switch and the third switch are closed and the first switch is open, and
(4) a fourth mode in which the first switch, the second switch, and the third switch are open, thereby maximizing the inductance component of the impedance matching circuit.

17. A communication device comprising:
the radio-frequency front-end circuit according to claim 15;
a controller configured to control states of connection of the first switch, the second switch, and the third switch; and
a RF-signal processing circuit configured to process the radio-frequency signal,
wherein the controller is configured to select a mode based on a frequency band of the radio-frequency signal, the mode being:
(1) a first mode in which the first switch, the second switch, and the third switch are closed, thereby minimizing an inductance component of the impedance matching circuit,
(2) a second mode in which the first switch and the second switch are closed and the third switch is open,
(3) a third mode in which the second switch and the third switch are closed and the first switch is open, and
(4) a fourth mode in which the first switch, the second switch, and the third switch are open, thereby maximizing the inductance component of the impedance matching circuit.
